(19) United States
(12) Patent Application Publication
(10) Pub. No.: US 2024/0364299 A1
(43) Pub. Date: Oct. 31, 2024

(54) BULK ACOUSTIC RESONATOR

(71) Applicant: Samsung Electro-Mechanics Co., Ltd., Suwon-si (KR)

(72) Inventors: Jong Woon KIM, Suwon-si (KR); Jeonga KIM, Suwon-si (KR); Jeong Hoon RYOU, Suwon-si (KR); Won HAN, Suwon-si (KR); Sang Uk SON, Suwon-si (KR); Tae Kyung LEE, Suwon-si (KR)

(73) Assignee: Samsung Electro-Mechanics Co., Ltd., Suwon-si (KR)

(21) Appl. No.: 18/608,106

(22) Filed: Mar. 18, 2024

(30) Foreign Application Priority Data
Apr. 28, 2023 (KR) 10-2023-0056485

(51) Int. Cl. H03H 9/02; H03H 9/13

(52) U.S. Cl. CPC H03H 9/02157; H03H 9/02023; H03H 9/132

(57) ABSTRACT

A bulk acoustic resonator includes an active region in which a first electrode disposed on a substrate, a piezoelectric layer disposed on the first electrode in a height direction, and a second electrode disposed on the piezoelectric layer in the height direction overlap each other in the height direction; a peripheral region in which the first electrode or the second electrode extends outwardly from the active region so that the first electrode and the second electrode do not overlap each other in the height direction in the peripheral region; and an auxiliary layer disposed in the peripheral region, wherein a first cutoff frequency of the active region is substantially equal to a second cutoff frequency of the peripheral region.

### CROSS-REFERENCE TO RELATED APPLICATIONS

This application claims the benefit under 35 USC 119 (a) of Korean Patent Application No. 10-2023-0056485 filed on Apr. 28, 2023, in the Korean Intellectual Property Office, the entire disclosure of which is incorporated herein by reference for all purposes.

### BACKGROUND

### 1. Field

The present disclosure relates to a bulk acoustic resonator.

### 2. Description of Related Art

With the recent rapid development of mobile communication devices and chemical and biological devices, the demand for small and lightweight filters, oscillators, resonant elements, and acoustic resonant mass sensors used in these devices is increasing.

Acoustic resonators, such as a Bulk Acoustic Wave (BAW) filter, may be used as small and lightweight filters, oscillators, resonant elements, and acoustic resonant mass sensors, and have small size and excellent performance compared to dielectric filters, metal cavity filters, waveguides, and devices, so they are widely used in communication modules of modern mobile devices that require high performance, such as a wide passband.

A bulk acoustic wave filter includes a plurality of bulk acoustic wave resonators, but the bulk acoustic wave resonators are subject to leakage of resonant energy due to the effects of lateral waves generated at a resonant frequency.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, a bulk acoustic resonator includes an active region in which a first electrode disposed on a substrate, a piezoelectric layer disposed on the first electrode in a height direction, and a second electrode disposed on the piezoelectric layer in the height direction overlap each other in the height direction; a peripheral region in which the first electrode or the second electrode extends outwardly from the active region so that the first electrode and the second electrode do not overlap each other in the height direction in the peripheral region; and an auxiliary layer disposed in the peripheral region, wherein a first cutoff frequency of the active region is substantially equal to a second cutoff frequency of the peripheral region.

The bulk acoustic resonator may further include a cavity disposed between the substrate and the first electrode, and overlapping the active region in the height direction, wherein a ratio of the second cutoff frequency to the first cutoff frequency may be from about 0.9 to about 1.1.

The bulk acoustic resonator may further include a boundary region disposed between the active region and the peripheral region, wherein an end of the extended first electrode or an end of the extended second electrode and an end of the auxiliary layer may overlap each other in the height direction in the boundary region.

A thickness of the end of the extended first electrode or a thickness of the end of the extended second electrode in the boundary region may be less than a thickness of an end of the first electrode or an end of the second electrode in the active region, and a thickness of an end of the auxiliary layer in the boundary region may be less than a thickness of the auxiliary layer in the peripheral region.

A surface height of the piezoelectric layer in the height direction may vary in the boundary region.

The bulk acoustic resonator may further include a trench region disposed between the active region and the boundary region, wherein a thickness of the second electrode in the trench region may be less than a thickness of the second electrode in the active region.

The auxiliary layer may further include an extending portion extending into the trench region, and the extending portion of the auxiliary layer may overlap the second electrode in the trench region in the height direction.

A thickness of the extending portion of the auxiliary layer may be less than a thickness of a remaining portion of the auxiliary layer.

The auxiliary layer may overlap the first electrode or the second electrode in the peripheral region with the piezoelectric layer interposed therebetween in the height direction.

The auxiliary layer may be disposed on a lateral surface of the first electrode or the second electrode in the active region.

The auxiliary layer may include an insulating material.

The auxiliary layer may include at least some of materials of the piezoelectric layer.

A ratio of a thickness of the auxiliary layer to a thickness of the piezoelectric layer may be from about 0.6 to about 0.8.

A ratio of a thickness of the first electrode and the second electrode to the thickness of the piezoelectric layer may be from about 0.4 to about 0.6.

A ratio of a thickness of the auxiliary layer to a thickness of the piezoelectric layer may be from about 0.5 to about 0.7.

A ratio of a thickness of the first electrode and the second electrode to the thickness of the piezoelectric layer may be from about 0.2 to about 0.4.

The piezoelectric layer may include aluminum nitride, the first electrode and the second electrode include molybdenum, and the auxiliary layer may include silicon dioxide.

The auxiliary layer may be disposed between the first electrode or the second electrode in the peripheral region and the piezoelectric layer.

The auxiliary layer may be in contact with the first electrode or the second electrode in the peripheral region.

The auxiliary layer may include an insulating layer or a conductive layer.

A ratio of a thickness of the auxiliary layer to a thickness of the piezoelectric layer may be from about 0.2 to about 0.4.

A ratio of a thickness of the first electrode and the second electrode to the thickness of the piezoelectric layer may be from about 0.4 to about 0.6.

A ratio of a thickness of the auxiliary layer to a thickness of the piezoelectric layer may be from about 0.1 to about 0.3.

A ratio of a thickness of the first electrode and the second electrode to the thickness of the piezoelectric layer may be from about 0.2 to about 0.4.

The piezoelectric layer may include aluminum nitride, the first electrode and the second electrode include molybdenum, and the auxiliary layer may include silicon dioxide.

The auxiliary layer may overlap the piezoelectric layer in the height direction with the first electrode or the second electrode in the peripheral region being interposed therebetween.

The auxiliary layer may be in contact with the first electrode or the second electrode in the peripheral region.

The auxiliary layer may include an insulating material or a conductive material.

A ratio of a thickness of the auxiliary layer to a thickness of the piezoelectric layer may be from about 0.7 to about 0.9.

A ratio of a thickness of the first electrode and the second electrode to the thickness of the piezoelectric layer may be from about 0.4 to about 0.6.

A ratio of a thickness of the auxiliary layer to a thickness of the piezoelectric layer may be from about 0.6 to about 0.8.

A ratio of a thickness of the first electrode and the second electrode to the thickness of the piezoelectric layer may be from about 0.2 to about 0.4.

The piezoelectric layer may include aluminum nitride, the first electrode and the second electrode include molybdenum, and the auxiliary layer may include silicon dioxide.

The bulk acoustic resonator may further include an acoustic reflector layer disposed within the substrate and overlapping the active region, wherein a ratio of the second cutoff frequency to the first cutoff frequency may be substantially equal to 1.

The ratio of the second cutoff frequency to the first cutoff frequency may be from about 0.9 to about 1.1.

The peripheral region may include a first peripheral region in which the first electrode extends outwardly from the active region and does not overlap the second electrode in the height direction; and a second peripheral region in which the second electrode extends outwardly from the active region and does not overlap the first electrode in the height direction, and the auxiliary layer may include a first auxiliary layer disposed in the first peripheral region and overlapping the extending first electrode in the height direction; and a second auxiliary layer disposed in the second peripheral region and overlapping the extending second electrode in the height direction.

The first auxiliary layer may be disposed between the piezoelectric layer and the first electrode, and the second auxiliary layer may overlap the second electrode in the height direction with the piezoelectric layer interposed therebetween.

In another general aspect, a bulk acoustic resonator includes an active region in which a first electrode, a piezoelectric layer disposed on the first electrode in a height direction, and a second electrode disposed on the piezoelectric layer in the height direction overlap each other in the height direction; and a peripheral region disposed on a circumference of the active region, wherein the piezoelectric layer, the auxiliary layer, and an extending portion of the first electrode or an extending portion of the second electrode extending outwardly from the active region overlap each other in the height direction, wherein a first cutoff frequency of the active region is substantially equal to a second cutoff frequency of the peripheral region.

The bulk acoustic resonator may further include a cavity overlapping the active region in the height direction, wherein a ratio of the second cutoff frequency to the first cutoff frequency may be from about 0.9 to about 1.1.

The bulk acoustic resonator may further include an acoustic reflector layer overlapping the active region in the height direction, wherein a ratio of the second cutoff frequency to the first cutoff frequency may be from about 0.9 to about 1.1.

In another general aspect, a bulk acoustic resonator includes an active region in which a first electrode disposed on a substrate, a piezoelectric layer disposed on the first electrode in a height direction, and a second electrode disposed on the piezoelectric layer in the height direction overlap each other in the height direction; a first peripheral region in which the first electrode and the piezoelectric layer extend outwardly from the active region so that the first electrode and the second electrode do not overlap each other in the height direction in the first peripheral region; a second peripheral region in which the second electrode and the piezoelectric layer extend outwardly from the active region so that the first electrode and the second electrode do not overlap each other in the height direction in the second peripheral region; a first auxiliary layer disposed in the first peripheral region so that the first electrode is disposed between the first auxiliary layer and the piezoelectric layer in the height direction in the first peripheral region; and a second auxiliary layer disposed in the second peripheral region so that the second electrode is disposed between the second auxiliary layer and the piezoelectric layer in the height direction in the second peripheral region.

A first cutoff frequency of the active region may be substantially equal to a second cutoff frequency of the first peripheral region and a third cutoff frequency of the second peripheral region.

A surface height of the first electrode in the height direction in the first peripheral region may be different from a surface height of the first electrode in the height direction in the active region, and a surface height of the second electrode in the height direction in the second peripheral region may be different from a surface height of the second electrode in the height direction in the active region.

A surface height of the first electrode in the height direction in the first peripheral region may be the same as a surface height of the first electrode in the height direction in the active region, and a surface height of the second electrode in the height direction in the second peripheral region may be the same as a surface height of the second electrode in the height direction in the active region.

A ratio of a thickness of the first auxiliary layer and the second auxiliary layer to a thickness of the piezoelectric layer may be from about 0.7 to about 0.9, and a ratio of a thickness of the first electrode and the second electrode to a thickness of the piezoelectric layer may be from about 0.4 to about 0.6.

A ratio of a thickness of the first auxiliary layer and the second auxiliary layer to a thickness of the piezoelectric layer may be from about 0.6 to about 0.8, and a ratio of a thickness of the first electrode and the second electrode to a thickness of the piezoelectric layer may be from about 0.2 to about 0.4.

Other features and aspects will be apparent from the following detailed description, the drawings, and the claims.

### BRIEF DESCRIPTION OF THE DRAWINGS

FIG. 1 is a top plan view schematically illustrating a bulk acoustic resonator according to an embodiment.

FIG. 2 is a cross-sectional view of the bulk acoustic resonator of FIG. 1 taken along the line II-II′ in FIG. 1.

FIG. 3 is a cross-sectional view schematically illustrating a bulk acoustic resonator according to another embodiment.

FIG. 4 is a cross-sectional view schematically illustrating a bulk acoustic resonator according to another embodiment.

FIG. 5 is a cross-sectional view schematically illustrating a bulk acoustic resonator according to another embodiment.

FIG. 6 is a cross-sectional view schematically illustrating a bulk acoustic resonator according to another embodiment.

FIG. 7 is a cross-sectional view schematically illustrating a bulk acoustic resonator according to another embodiment.

FIG. 8 is a cross-sectional view schematically illustrating a bulk acoustic resonator according to another embodiment.

FIG. 9 is a cross-sectional view schematically illustrating a bulk acoustic resonator according to another embodiment.

FIG. 10 is a cross-sectional view schematically illustrating a bulk acoustic resonator according to another embodiment.

FIG. 11 is a top plan view illustrating a portion of a bulk acoustic resonator filter according to an embodiment.

FIG. 12 is a perspective view of a bulk acoustic resonator filter package according to an embodiment including the bulk acoustic resonator filter of FIG. 11.

FIG. 13 is a perspective view illustrating a bulk acoustic resonator filter package substrate including the bulk acoustic resonator filter package of FIG. 12.

FIG. 14 is a perspective view of a bulk acoustic resonator filter package according to another embodiment.

FIG. 15 is a perspective view illustrating a bulk acoustic resonator filter package substrate including the bulk acoustic resonator filter package of FIG. 14.

FIGS. 16 to 18 are graphs illustrating results of one experimental example of a bulk acoustic resonator.

FIGS. 19 to 21 are graphs illustrating results of another experimental example of a bulk acoustic resonator.

Throughout the drawings and the detailed description, the same reference numerals refer to the same elements. The drawings may not be to scale, and the relative sizes, proportions, and depictions of elements in the drawings may be exaggerated for clarity, illustration, and convenience.

### DETAILED DESCRIPTION OF THE EMBODIMENTS

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of functions and constructions that would be well known to one of ordinary skill in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The use of the term “may” with respect to an example or embodiment, e.g., as to what an example or embodiment may include or implement, means that at least one example or embodiment exists in which such a feature is included or implemented, while all examples and embodiments are not necessarily limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as illustrated in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated by 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

The features of the examples described herein may be combined in various ways as will be apparent after an understanding of the disclosure of this application. Further, although the examples described herein have a variety of configurations, other configurations are possible as will be apparent after an understanding of the disclosure of this application.

In addition, the size and thickness of each configuration illustrated in the drawings are arbitrarily illustrated for understanding and ease of description, but the embodiments are not limited thereto. In the drawings, the thicknesses of layers, films, panels, regions, and other elements are exaggerated for clarity. In the drawings, for understanding and ease of description, the thicknesses of some layers and areas is exaggerated.

Furthermore, with respect to the drawings, “plan view” means that a target part is viewed from above, and “cross-sectional view” means that a cross section obtained by cutting a target part vertically is viewed from the side.

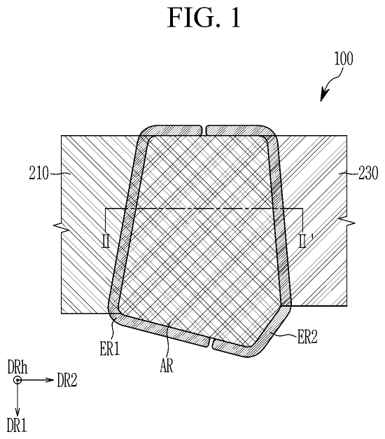

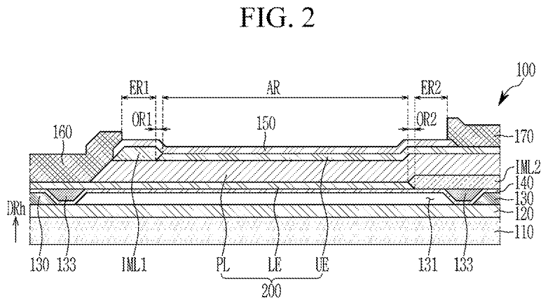

FIG. 1 is a top plan view schematically illustrating a bulk acoustic resonator according to an embodiment, and FIG. 2 is a cross-sectional view of the bulk acoustic resonator of FIG. 1 taken along the line II-II′ in FIG. 1.

Referring to FIG. 1, a bulk acoustic resonator 100 may include a region in which a first electrode 210 and a second electrode 230 partially overlap in height direction DRh perpendicular to a plane formed by a first direction DR1 and a second direction DR2 extending in different directions. The bulk acoustic resonator 100 may include an active region AR in which the first electrode 210 and the second electrode 230 overlap each other, and peripheral regions ER1 and ER2 disposed along the edges of the active region AR. This will be described in more detail below.

Referring to FIG. 2, the bulk acoustic resonator 100 according to the embodiment may include a substrate 110, a resonant portion 200 disposed above the substrate 110, a first auxiliary layer IML1, a second auxiliary layer IML2, an insulating layer 120 disposed between the substrate 110 and the resonant portion 200, a cavity 131, a support layer 130 surrounding the cavity 131, and an anti-etch portion 133.

The substrate 110 may include silicon. For example, the substrate 110 may be, but is not limited to, a silicon substrate or a silicon on insulator (SOI) substrate.

The substrate 110 and the resonant portion 200 may be electrically insulated from each other by the insulating layer 120 disposed on the substrate 110. Furthermore, the insulating layer 120 may prevent the substrate 110 from being etched by an etching gas used to form the cavity 131.

The insulating layer 120 may include, but is not limited to, any one or any combination of any two or more of silicon dioxide (SiO₂), silicon nitride (Si₃N₄), aluminum oxide (Al₂O₃), and aluminum nitride (AlN).

The support layer 130 may be disposed on the insulating layer 120, and the support layer 130 may be disposed around the periphery of the cavity 131 and the anti-etch portion 133 and may be disposed to surround the cavity 131 and the anti-etch portion 133.

The support layer 130 may include, but is not limited to, a polysilicon or polymer that may be etched by the etching gas used to form the cavity 131.

The cavity 131 may be an empty space, and may be formed by removing a portion of a sacrificial layer formed on the substrate 110, and the support layer 130 may be formed from a remaining portion of the sacrificial layer.

The anti-etch portion 133 may be disposed along the boundary of the cavity 131. The anti-etch portion 133 may prevent etching from progressing beyond the area where the cavity 131 is to be formed during the formation of the cavity 131.

When the cavity 131 is formed, a halide-based etching gas including fluorine (F) or chlorine (Cl) may be used to remove a portion of the sacrificial layer. The anti-etch portion 133 may include materials that are more difficult to be etched by the halide-based etching gas than the support layer 130. For example, the anti-etch portion 133 may include either one or both of silicon dioxide (SiO₂) and silicon nitride (Si₃N₄), but is not limited thereto.

The resonant portion 200 may include a first electrode LE, a piezoelectric layer PL, and a second electrode UE, which are sequentially disposed in the height direction DRh perpendicular to the surface of the substrate 110 and overlap each other.

In the height direction DRh, which is perpendicular to the plane formed by the first direction DR1 and the second direction DR2, the first electrode LE of the resonant portion 200 may be disposed above the substrate 110, the piezoelectric layer PL may be disposed above the first electrode LE, and the second electrode UE may be disposed above the piezoelectric layer PL.

The piezoelectric layer PL of the resonant portion 200 may be disposed between the first electrode LE and the second electrode UE.

The resonant portion 200 may be spaced from the support substrate 110 by the cavity 131, and the resonant portion 200 may be arranged to overlap the cavity 131, thereby vibrating in a predetermined direction.

The resonant portion 200 may resonate the piezoelectric layer PL according to the signal applied to the first electrode LE and the second electrode UE to generate a resonant frequency and an anti-resonant frequency.

The first electrode LE and the second electrode UE may include a conductor. For example, the first electrode LE and the second electrode UE may include a metal, and for example, the first electrode LE and the second electrode UE may include, but are not limited to, any one or any combination of any two or more of gold, molybdenum, ruthenium, iridium, aluminum, platinum, titanium, tungsten, palladium, tantalum, chromium, and nickel.

The first electrode LE and the second electrode UE may be an input electrode and an output electrode that input and output electrical signals, such as radio-frequency (RF) signals.

When the first electrode LE is an input electrode, the second electrode UE may be an output electrode, and when the first electrode LE is an output electrode, the second electrode UE may be an input electrode.

The piezoelectric layer PL may be a portion that produces the piezoelectric effect, which converts electrical energy into mechanical energy in the form of acoustic waves.

The piezoelectric layer PL may include any one or any combination of any two or more of zinc oxide (ZnO), aluminum nitride (AlN), doped aluminum nitride, lead zirconate titanate, and quartz. The doped aluminum nitride may further include a rare earth metal, a transition metal, or an alkaline earth metal. The rare earth metal may include any one or any combination of any two or more of scandium (Sc), erbium (Er), yttrium (Y), and lanthanum (La). The transition metal may include any one or any combination of any two or more of hafnium (Hf), titanium (Ti), zirconium (Zr), tantalum (Ta), and niobium (Nb). The alkaline earth metal may include magnesium (Mg). The amount of the elements doped into the aluminum nitride (AlN) to form the doped aluminum nitride may range from 0.1 to 30 at %.

The piezoelectric layer PL may include a material in which aluminum nitride (AlN) is doped with scandium (Sc), and the piezoelectric layer PL includes the doped material, so that the piezoelectric constant may be increased, thereby increasing an electromechanical coupling factor (kt₂) of the acoustic resonator.

The first auxiliary layer IML1 may be disposed on the lateral surface of the edge of the second electrode UE, and the second auxiliary layer IML2 may be disposed on the lateral surface of the edge of the first electrode LE. However, the present disclosure is not limited thereto, and either one or both of the first auxiliary layer IML1 and the second auxiliary layer IML2 may be disposed at a different location.

The first auxiliary layer IML1 and the second auxiliary layer IML2 may include an insulating layer. The first auxiliary layer IML1 and the second auxiliary layer IML2 may include at least some of the materials that the piezoelectric layer PL includes.

The first auxiliary layer IML1 and the second auxiliary layer IML2 may include, but are not limited to, silicon dioxide (SiO₂).

The first auxiliary layer IML1 may have a greater thickness than the second electrode UE, and the second auxiliary layer IML2 may have a greater thickness than the first electrode LE.

A protective layer 150 may be disposed on the second electrode UE and the first auxiliary layer IML1 of the resonant portion 200.

The first electrode LE and the second electrode UE may extend outwardly from the resonant portion 200, and an extending portion of the first electrode LE and an extending portion of the second electrode UE extending outwardly from the resonant portion 200 may be connected to a first connection portion 160 and a second connection portion 170.

An edge portion of the first electrode LE extending outwardly from the resonant portion 200 may not overlap the protective layer 150 in the height direction DRh, and an edge portion of the first electrode LE not overlapping the piezoelectric layer PL in the height direction DRh may be connected to the first connection portion 160. An edge portion of the second electrode UE extending outwardly from the resonant portion 200 may not overlap the protective layer 150 in the height direction DRh, and an edge of the second electrode UE not overlapping the protective layer 150 in the height direction DRh may be connected to the second connection portion 170.

The first connection portion 160 and the second connection portion 170 may serve as connection wiring to electrically connect to electrodes of additional bulk acoustic resonators disposed above the substrate 110, or may serve as an input electrode and an output electrode to input and output electrical signals.

The ends of the protective layer 150 may be in contact with the first connection portion 160 and the second connection portion 170, thereby enabling heat generated in the piezoelectric layer PL to be transferred through the protective layer 150 to the first connection portion 160 and the second connection portion 170 to be dissipated.

The resonant portion 200 may include an active region AR in which the first electrode LE, the piezoelectric layer PL, and the second electrode UE overlap each other in the height direction DRh. The active region AR may include the first electrode LE, the piezoelectric layer PL, and the second electrode UE overlapping each other in the height direction DRh, and the thicknesses of the first electrode LE, the piezoelectric layer PL, and the second electrode UE in the active region AR may be substantially constant.

The peripheral regions ER1 and ER2 disposed adjacent to an edge of the active region AR may include a first peripheral region ER1 in which the first electrode LE extending outwardly from the active region AR and not overlapping the second electrode UE in the height direction DRh is disposed, and a second peripheral region ER2 in which the second electrode UE extending outwardly from the active region AR and not overlapping the first electrode LE in the height direction DRh is disposed.

The first peripheral region ER1 may be a region where the first electrode LE, the piezoelectric layer PL, and the first auxiliary layer IML1 overlap each other in the height direction DRh, and the second peripheral region ER2 may be a region where the second auxiliary layer IML2, the piezoelectric layer PL, and the second electrode UE overlap each other in the height direction DRh.

The peripheral regions ER1 and ER2 may be regions disposed along the circumference of the active region AR. Thus, the peripheral regions ER1 and ER2 are regions that extend outwardly from the active region AR and may be disposed in a continuous ring shape along the circumference of the active region AR. However, the present disclosure is not limited thereto.

A first cutoff frequency of the active region AR of the resonant portion 200 and a second cutoff frequency of the first peripheral region ER1 may be substantially equal to each other. A ratio (Fc1) of the second cutoff frequency to the first cutoff frequency may be from about 0.9 to about 1.1, and more specifically, the ratio (Fc1) of the second cutoff frequency to the first cutoff frequency may be from about 0.935 to about 1. Furthermore, the first cutoff frequency of the active region AR and a third cutoff frequency of the second peripheral region ER2 may be substantially equal to each other. A ratio (Fc2) of the third cutoff frequency to the first cutoff frequency may be from about 0.9 to about 1.1, and more specifically, from about 0.935 to about 1.

The first electrode LE and the second electrode UE include molybdenum (Mo), the piezoelectric layer PL includes aluminum nitride AlN, and the first auxiliary layer IML1 and the second auxiliary layer IML2 include silicon dioxide SiO₂, and when the thickness of the piezoelectric layer PL is 1, the thickness of the first electrode LE and the second electrode UE may be from about 0.4 to about 0.6, and more specifically, about 0.529, and the thickness of the first auxiliary layer IML1 and the second auxiliary layer IML2 may be from about 0.6 to about 0.8, and more specifically, from about 0.693 to about 0.765.

More specifically, when the thickness of the piezoelectric layer PL is 1, the thickness of the first electrode LE and the second electrode UE may be from about 0.4 to about 0.6, and more specifically, the thickness of the first electrode LE and the second electrode UE may be about 0.529. When the thickness of the piezoelectric layer PL is 1, the thickness of the first auxiliary layer IML1 and the second auxiliary layer IML2 may be about 0.6 to about 0.8, and more specifically, the thickness of the first auxiliary layer IML1 and the second auxiliary layer IML2 may be about 0.693. In this case, the first cutoff frequency of the active region AR of the resonant portion 200 may be substantially equal to the second cutoff frequency of the first peripheral region ER1 and the third cutoff frequency of the second peripheral region ER2.

Alternatively, when the thickness of the piezoelectric layer PL is 1, the thickness of the first electrode LE and the second electrode UE may be about 0.4 to about 0.6, and more specifically, the thickness of the first electrode LE and the second electrode UE may be about 0.529. The thickness of the first auxiliary layer IML1 and the second auxiliary layer IML2 may be from about 0.6 to about 0.8, and more specifically, may be about 0.765. In this case, the ratio (Fc1) of the second cutoff frequency of the first peripheral region ER1 to the first cutoff frequency of the active region AR of the resonant portion 200 and the ratio (Fc2) of the third cutoff frequency of the second peripheral region ER2 to the first cutoff frequency of the active region AR may be from about 0.9 to about 1.1, and more specifically, may be about 0.935.

Alternatively, when the thickness of the piezoelectric layer PL is 1, the thickness of the first electrode LE and the second electrode UE may be about 0.2 to about 0.4, and more specifically, the thickness of the first electrode LE and the second electrode UE may be about 0.313, and the thickness of the first auxiliary layer IML1 and the second auxiliary layer IML2 may be from about 0.5 to about 0.7, and more specifically, from about 0.583 to about 0.652. In this case, the ratio (Fc1) of the second cutoff frequency of the first peripheral region ER1 to the first cutoff frequency of the active region AR of the resonant portion 200 and the ratio (Fc2) of the third cutoff frequency of the second peripheral region ER2 to the first cutoff frequency of the active region AR may be from about 0.9 to about 1.1.

When an acoustic impedance of the active region AR of the resonant portion 200 is different from an acoustic impedance of the first peripheral region ER1 and the second peripheral region ER2 disposed at the edges of the active region AR, lateral waves generated in the active region AR and propagating outwardly may be reflected from the first peripheral region ER1 and the second peripheral region ER2 and propagate back into the active region AR, and this may reduce energy dissipation in the active region AR. However, due to the difference in acoustic impedance depending on the location, the lateral waves reflected from the first peripheral region ER1 and the second peripheral region ER2 and propagated back into the active region AR may be amplified by forming a standing wave within the active region AR, and the unnecessarily amplified lateral waves may increase the viscoelastic loss within the active region AR, which affects the resonant energy of the active region AR, thereby reducing the resonant energy of the active region AR.

According to the bulk acoustic resonator 100 according to the present embodiment, the first cutoff frequency of the active region AR may be substantially equal to the second cutoff frequency of the first peripheral region ER1 and the third cutoff frequency of the second peripheral region ER2, and the ratio (Fc1) of the second cutoff frequency to the first cutoff frequency and the ratio (Fc2) of the third cutoff frequency to the first cutoff frequency may be from about 0.9 to about 1.1, and more specifically, from about 0.935 to about 1.

As such, the first cutoff frequency of the active region AR may be substantially equal to the second cutoff frequency of the first peripheral region ER1 and the third cutoff frequency of the second peripheral region ER2, the acoustic impedance of the active region AR may be substantially equal to the acoustic impedance of the first peripheral region ER1 and the acoustic impedance of the second peripheral region ER2, and the lateral waves generated in the active region AR and propagating outwardly may not be reflected back into the active region AR from the first peripheral region ER1 and the second peripheral region ER2. This reduces the resonant energy of the active region AR from being reduced by unnecessarily amplified lateral waves.

When the ratio (Fc1 or Fc2) of the second cutoff frequency of the first peripheral region ER1 or the third cutoff frequency of the second peripheral region ER2 to the first cutoff frequency of the active region AR is about 1, the acoustic impedance of the active region AR is equal to the acoustic impedance of the first peripheral region ER1 and the acoustic impedance of the second peripheral region ER2, so that the lateral waves generated in the active region AR may not be reflected back to the active region AR from the first peripheral region ER1 and the second peripheral region ER2.

As the ratio (Fc1 or Fc2) of the second cutoff frequency of the first peripheral region ER1 or the third cutoff frequency of the second peripheral region ER2 to the first cutoff frequency of the active region AR becomes smaller than 1, the difference between the acoustic impedance of the active region AR and the acoustic impedance of the first peripheral region ER1 and the acoustic impedance of the second peripheral region ER2 becomes larger, so that the amount of resonance energy reduction due to reflection of the lateral waves may become larger.

In particular, when the ratio (Fc2 or Fc2) of the second cutoff frequency of the first peripheral region ER1 or the third cutoff frequency of the second peripheral region ER2 to the first cutoff frequency of the active region AR becomes less than about 0.9, and more specifically, less than about 0.935, the reflected and re-propagated lateral waves may be amplified and mode-converted, and the resonant energy reduction of the active region AR may rapidly increase.

Furthermore, when the ratio (Fc2 or Fc2) of the second cutoff frequency of the first peripheral region ER1 or the third cutoff frequency of the second peripheral region ER2 to the first cutoff frequency of the active region AR is greater than about 1.1, and more specifically, greater than about 1, an evanescent wave may be converted into a propagating wave by dispersion, resulting in a large energy loss in the in-band between the resonant frequency and the anti-resonant frequency of the active region AR.

According to the bulk acoustic resonator 100 according to the present embodiment, the first cutoff frequency of the active region AR may be substantially equal to the second cutoff frequency of the first peripheral region ER1 and the third cutoff frequency of the second peripheral region ER2, and more specifically, the ratio (Fc1) of the second cutoff frequency to the first cutoff frequency and the ratio (Fc2) of the third cutoff frequency to the first cutoff frequency may be from about 0.9 to about 1.1, and therefor the resonant energy loss of the active region AR due to re-injection of the lateral waves may be reduced.

A first boundary region OR1 where the end of the second electrode UE overlaps the end of the first auxiliary layer IML1 and a second boundary region OR2 where the end of the first electrode LE overlaps the end of the second auxiliary layer IML2 may be disposed between the active region AR and the peripheral regions ER1 and ER2.

In manufacturing the first electrode LE and the second electrode UE in which a metal layer is deposited and etched, the end of the second electrode UE disposed in the first boundary region OR1 and the end of the first electrode LE disposed in the second boundary region OR2 may have a tapered structure whose thickness gradually decreases toward the edge, and as such, when the thickness of the first electrode LE and the second electrode UE varies, the acoustic impedance in this region may vary.

However, according to the bulk acoustic resonator 100 according to the present embodiment, the end of the thickness-varying tapered second electrode UE disposed in the first boundary region OR1 may overlap the end of the tapered first auxiliary layer IML1, and the end of the tapered first electrode LE disposed in the second boundary region OR2 may overlap the end of the tapered second auxiliary layer IML2. Therefore, the change in the acoustic impedance in the first boundary region OR1 and the second boundary region OR2, where the end of the second electrode UE and the end of the first electrode LE, whose thickness varies, are disposed, may be reduced, thereby preventing the lateral waves from being reflected in the first boundary region OR1 and the second boundary region OR2 and propagated back to the active region AR.

Next, a method of calculating a cutoff frequency will be simply described. The cutoff frequency may be the frequency at which mechanical resonance occurs and may be calculated by subtracting the electrical item from the Mason Model as shown below.

On the top and bottom surfaces of the i-th layer with n layers stacked as above, the following relations, two for each layer and 2n in total, are established.

$$\{ \begin{matrix}{F}_{i - 1} \\ {F}_{i}\end{matrix} \} = [ \begin{matrix}\begin{matrix}\frac{\sqrt{{ρ}_{i} {c}_{i}}}{j sin ( \frac{2 {d}_{i}}{\sqrt{{c}_{i} / {ρ}_{i}}} ω )} + \\ j \sqrt{{ρ}_{i} {c}_{i}} tan ( \frac{{d}_{i}}{\sqrt{{c}_{i} / {ρ}_{i}}} ω )\end{matrix} & - \frac{\sqrt{{ρ}_{i} {c}_{i}}}{j sin ( \frac{2 {d}_{i}}{\sqrt{{c}_{i} / {ρ}_{i}}} ω )} \\ \frac{\sqrt{{ρ}_{i} {c}_{i}}}{j sin ( \frac{2 {d}_{i}}{\sqrt{{c}_{i} / {ρ}_{i}}} ω )} & \begin{matrix}- \frac{\sqrt{{ρ}_{i} {c}_{i}}}{j sin ( \frac{2 {d}_{i}}{\sqrt{{c}_{i} / {ρ}_{i}}} ω )} - \\ j \sqrt{{ρ}_{i} {c}_{i}} tan ( \frac{{d}_{i}}{\sqrt{{c}_{i} / {ρ}_{i}}} ω )\end{matrix}\end{matrix} ]$$

$$\{ \begin{matrix}{v}_{i - 1} \\ {v}_{i}\end{matrix} \} = [ \begin{matrix}{a}_{i}^{11} & {a}_{i}^{12} \\ {a}_{i}^{21} & {a}_{i}^{22}\end{matrix} ] \{ \begin{matrix}{v}_{i - 1} \\ {v}_{i}\end{matrix} \}$$

The definitions of the various terms are as follows.
i=1, . . . , n ω=angular frequency
Fᵢ₋₁=stress at bottom surface of i-th layer
Fᵢ=stress at top surface of i-th layer
vᵢ₋₁=particle velocity at bottom surface of l-th layer
vᵢ=particle velocity at top surface of i-th layer

Also, ρ, c, and d are values determined by properties and dimensions in the thickness direction.
ρᵢ=density of i-th layer
cᵢ=stiffness of i-th layer
2dᵢ=thickness of i-th layer

The relationship between the 2n+2 unknowns (F₀, . . . , Fₙ and v₀, . . . , vₙ) and the 2n equations and 2 boundary conditions described before, totaling 2n+2 equations, is represented by a (2n+2)×(2n+2) matrix as shown below. The first and last rows may be the boundary conditions at the top and bottom surfaces of the entire stack structure (F₀=Fₙ=0).

When the (2n+2)×(2n+2) matrix is denoted by [B(ω)], the value of [B(ω)] is calculated according to ω, and the resonant frequency may be determined through the frequency response of the matrix values. For example, when the following characteristic equation represents the resonance condition, the resonance frequency (ω_{c}) that satisfies the following equation may be calculated.

det([B])˜0

From this, the cutoff frequency (Fc) may be determined by the following equation

$$Fc = {ω}_{c} / 2 π$$

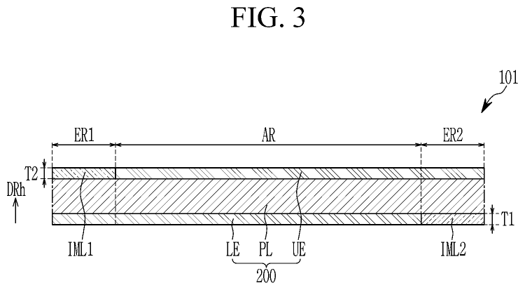

FIG. 3 is a cross-sectional view illustrating a bulk acoustic resonator according to another embodiment.

Referring to FIG. 3, a bulk acoustic resonator 101 includes a resonant portion 200, and a first auxiliary layer IML1, and a second auxiliary layer IML2. A substrate 110, an insulating layer 120, a cavity 131, and other elements shown in FIG. 2 are omitted from FIG. 3. The features of the configurations according to the embodiment described with reference to FIG. 2 are applicable to all configurations not illustrated in FIG. 3.

Referring to FIG. 3, the bulk acoustic resonator 101 according to the present embodiment is similar to the bulk acoustic resonator 100 according to the embodiment described with reference to FIG. 2. Specific descriptions of the same components are omitted.

As illustrated in FIG. 3, the bulk acoustic resonator 101 according to the present embodiment may include a resonant portion 200 including a first electrode LE, a piezoelectric layer PL, a second electrode UE, a first auxiliary layer IML1, and a second auxiliary layer IML2.

The resonant portion 200 may include an active region AR in which the first electrode LE, the piezoelectric layer PL, and the second electrode UE overlap each other in the height direction DRh. The active region AR may be a portion in which the thicknesses of the first electrode LE, the piezoelectric layer PL, and the second electrode UE overlapping each other in the height direction DRh are substantially constant.

Peripheral regions ER1 and ER2 disposed adjacent to an edge of the active region AR may include a first peripheral region ER1 in which the first electrode LE extending outwardly from the active region AR and not overlapping the second electrode UE in the height direction DRh is disposed, and a second peripheral region ER2 in which the second electrode UE extending outwardly from the active region AR and not overlapping the first electrode LE in the height direction DRh is disposed.

The first auxiliary layer IML1 may be disposed in the first peripheral region ER1, and the second auxiliary layer IML2 may be disposed in the second peripheral region ER2.

The first auxiliary layer IML1 may be disposed at a lateral surface of an edge of the second electrode UE, and the second auxiliary layer IML2 may be disposed at a lateral surface of an edge of the first electrode LE, but the present disclosure is not limited to, and either one or both of the first auxiliary layer IML1 and the second auxiliary layer IML2 may be disposed at a different location.

The first auxiliary layer IML1 and the second auxiliary layer IML2 may include an insulating layer. The first auxiliary layer IML1 and the second auxiliary layer IML2 may include at least some of the materials that the piezoelectric layer PL includes.

The first auxiliary layer IML1 and the second auxiliary layer IML2 may include, but are not limited to, silicon dioxide SiO₂.

However, according to the bulk acoustic resonator 101 according to the present embodiment, unlike the bulk acoustic resonator 100 according to the embodiment previously described with reference to FIG. 2, a first thickness T1 of the second auxiliary layer IML2 adjacent to the first electrode LE may be substantially equal to a thickness of the first electrode LE, and a second thickness T2 of the first auxiliary layer IML1 adjacent to the second electrode UE may be substantially equal to a thickness of the second electrode UE.

The first peripheral region ER1 may be a region where the first electrode LE, the piezoelectric layer PL, and the first auxiliary layer IML1 overlap each other in the height direction DRh, and the second peripheral region ER2 may be a region where the second auxiliary layer IML2, the piezoelectric layer PL, and the second electrode UE overlap each other in the height direction DRh.

A first cutoff frequency of the active region AR of the resonant portion 200 and a second cutoff frequency of the first peripheral region ER1 may be substantially equal to each other. The ratio (Fc1) of the second cutoff frequency to the first cutoff frequency may be from about 0.9 to about 1.1. More specifically, the ratio (Fc1) of the second cutoff frequency to the first cutoff frequency may be from about 0.935 to about 1. Furthermore, the first cutoff frequency of the active region AR and a third cutoff frequency of the second peripheral region ER2 may be substantially equal to each other. The ratio (Fc2) of the third cutoff frequency to the first cutoff frequency may be from about 0.9 to about 1.1. More specifically, the ratio (Fc2) of the third cutoff frequency to the first cutoff frequency may be from about 0.935 to about 1.

The first electrode LE and the second electrode UE include molybdenum (Mo), the piezoelectric layer PL includes aluminum nitride AlN, and the first auxiliary layer IML1 and the second auxiliary layer IML2 include silicon dioxide SiO₂, and when the thickness of the piezoelectric layer PL is 1, the thickness of the first electrode LE and the second electrode UE may be from about 0.4 to about 0.6, and more specifically, about 0.529, and the thickness of the first auxiliary layer IML1 and the second auxiliary layer IML2 may be from about 0.6 to about 0.8, and more specifically, from about 0.693 to about 0.765.

More specifically, when the thickness of the piezoelectric layer PL is 1, the thickness of the first electrode LE and the second electrode UE may be from about 0.4 to about 0.6, and more specifically, the thickness of the first electrode LE and the second electrode UE may be about 0.529. When the thickness of the piezoelectric layer PL is 1, the thickness of the first auxiliary layer IML1 and the second auxiliary layer IML2 may be about 0.6 to about 0.8, and more specifically, the thickness of the first auxiliary layer IML1 and the second auxiliary layer IML2 may be about 0.693. In this case, the first cutoff frequency of the active region AR of the resonant portion 200 and the second cutoff frequency of the first peripheral region ER1 and the third cutoff frequency of the second peripheral region ER2 may be substantially equal to each other.

Alternatively, when the thickness of the piezoelectric layer PL is 1, the thickness of the first electrode LE and the second electrode UE may be about 0.4 to about 0.6, and more specifically, the thickness of the first electrode LE and the second electrode UE may be about 0.529. The thickness of the first auxiliary layer IML1 and the second auxiliary layer IML2 may be from about 0.6 to about 0.8, and more specifically, may be about 0.765. In this case, the ratio (Fc1) of the second cutoff frequency of the first peripheral region ER1 to the first cutoff frequency of the active region AR of the resonant portion 200 and the ratio (Fc2) of the third cutoff frequency of the second peripheral region ER2 to the first cutoff frequency of the active region AR may be from about 0.9 to about 1.1, and more specifically, may be about 0.935.

Alternatively, when the thickness of the piezoelectric layer PL is 1, the thickness of the first electrode LE and the second electrode UE may be about 0.2 to about 0.4, and more specifically, the thickness of the first electrode LE and the second electrode UE may be about 0.313, and the thickness of the first auxiliary layer IML1 and the second auxiliary layer IML2 may be from about 0.5 to about 0.7, and more specifically, from about 0.583 to about 0.652. In this case, the ratio (Fc1) of the second cutoff frequency of the first peripheral region ER1 to the first cutoff frequency of the active region AR of the resonant portion 200 and the ratio (Fc2) of the third cutoff frequency of the second peripheral region ER2 to the first cutoff frequency of the active region AR may be from about 0.9 to about 1.1.

Thus, according to the bulk acoustic resonator 102 according to the present embodiment, the first cutoff frequency of the active region AR may be substantially equal to the second cutoff frequency of the first peripheral region ER1 and the third cutoff frequency of the second peripheral region ER2, so that the acoustic impedance of the active region AR may be substantially equal to the acoustic impedance of the first peripheral region ER1 and the acoustic impedance of the second peripheral region ER2, and lateral waves generated in the active region AR and propagating outwardly may not be reflected back into the active region AR from the first peripheral region ER1 and the second peripheral region ER2. This reduces the resonant energy of the active region AR from being reduced by unnecessarily amplified lateral waves.

Many of the features of the bulk acoustic resonator 100 according to the embodiment described with reference to FIG. 2 are also applicable to the bulk acoustic resonator 101 according to the present embodiment.

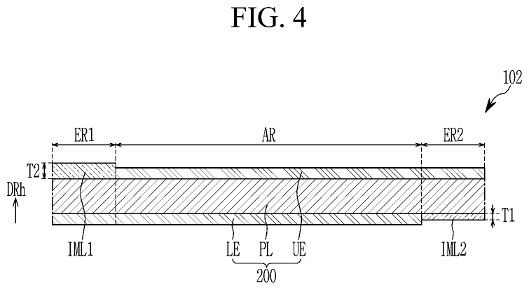

FIG. 4 is a cross-sectional view schematically illustrating a bulk acoustic resonator according to another embodiment.

Referring to FIG. 4, a bulk acoustic resonator 102 includes a resonant portion 200, a first auxiliary layer IML1, and a second auxiliary layer IML2. A substrate 110, an insulating layer 120, a cavity 131, and other elements shown in FIG. 2 are omitted from FIG. 4. The features of the configurations according to the embodiments described with reference to FIG. 2 are applicable to all configurations not illustrated in FIG. 4.

Referring to FIG. 4, the bulk acoustic resonator 102 according to the present embodiment is similar to the bulk acoustic resonators 100 and 101 according to the previously described embodiments. Specific descriptions of the same components are omitted.

As illustrated in FIG. 4, the bulk acoustic resonator 102 according to the present embodiment may include a resonant portion 200 including a first electrode LE, a piezoelectric layer PL, a second electrode UE, a first auxiliary layer IML1, and a second auxiliary layer IML2.

The resonant portion 200 may include an active region AR in which the first electrode LE, the piezoelectric layer PL, and the second electrode UE overlap each other in the height direction DRh. The active region AR may be a portion in which the thicknesses of the first electrode LE, the piezoelectric layer PL, and the second electrode UE overlapping each other in the height direction DRh are substantially constant.

Peripheral regions ER1 and ER2 disposed adjacent to an edge of the active region AR may include a first peripheral region ER1 in which the first electrode LE extending outwardly from the active region AR and not overlapping the second electrode UE in the height direction DRh is disposed, and a second peripheral region ER2 in which the second electrode UE extending outwardly from the active region AR and not overlapping the first electrode LE in the height direction DRh is disposed.

The first auxiliary layer IML1 may be disposed in the first peripheral region ER1, and the second auxiliary layer IML2 may be disposed in the second peripheral region ER2.

The first auxiliary layer IML1 may be disposed at a lateral surface of an edge of the second electrode UE, and the second auxiliary layer IML2 may be disposed at a lateral surface of an edge of the first electrode LE, but the present disclosure is not limited to, and either one or both of the first auxiliary layer IML1 and the second auxiliary layer IML2 may be disposed at a different location.

The first auxiliary layer IML1 and the second auxiliary layer IML2 may include an insulating layer. The first auxiliary layer IML1 and the second auxiliary layer IML2 may include at least some of the materials that the piezoelectric layer PL includes.

The first auxiliary layer IML1 and the second auxiliary layer IML2 may include, but are not limited to, silicon dioxide SiO₂.

However, according to the bulk acoustic resonator 102 according to the present embodiment, unlike the bulk acoustic resonators 100 and 101 according to the previously described embodiments, a first thickness T1 of the second auxiliary layer IML2 adjacent to the first electrode LE may be less than the thickness of the first electrode LE, and a second thickness T2 of the first auxiliary layer IML1 adjacent to the second electrode UE may be greater than the thickness of the second electrode UE.

The first peripheral region ER1 may be a region where the first electrode LE, the piezoelectric layer PL, and the first auxiliary layer IML1 overlap each other in the height direction DRh, and the second peripheral region ER2 may be a region where the second auxiliary layer IML2, the piezoelectric layer PL, and the second electrode UE overlap each other in the height direction DRh.

A first cutoff frequency of the active region AR of the resonant portion 200 and a second cutoff frequency of the first peripheral region ER1 may be substantially equal to each other. The ratio (Fc1) of the second cutoff frequency to the first cutoff frequency may be from about 0.9 to about 1.1. More specifically, the ratio (Fc1) of the second cutoff frequency to the first cutoff frequency may be from about 0.935 to about 1. Furthermore, the first cutoff frequency of the active region AR and a third cutoff frequency of the second peripheral region ER2 may be substantially equal to each other. The ratio (Fc2) of the third cutoff frequency to the first cutoff frequency may be from about 0.9 to about 1.1. More specifically, the ratio (Fc2) of the third cutoff frequency to the first cutoff frequency may be from about 0.935 to about 1.

The first electrode LE and the second electrode UE include molybdenum (Mo), the piezoelectric layer PL includes aluminum nitride AlN, and the first auxiliary layer IML1 and the second auxiliary layer IML2 include silicon dioxide SiO₂, and when the thickness of the piezoelectric layer PL is 1, the thickness of the first electrode LE and the second electrode UE may be from about 0.4 to about 0.6, and more specifically, about 0.529, and the thickness of the first auxiliary layer IML1 and the second auxiliary layer IML2 may be from about 0.6 to about 0.8, and more specifically, from about 0.693 to about 0.765.

More specifically, when the thickness of the piezoelectric layer PL is 1, the thickness of the first electrode LE and the second electrode UE may be from about 0.4 to about 0.6, and more specifically, the thickness of the first electrode LE and the second electrode UE may be about 0.529. When the thickness of the piezoelectric layer PL is 1, the thickness of the first auxiliary layer IML1 and the second auxiliary layer IML2 may be about 0.6 to about 0.8, and more specifically, the thickness of the first auxiliary layer IML1 and the second auxiliary layer IML2 may be about 0.693. In this case, the first cutoff frequency of the active region AR of the resonant portion 200 may be substantially equal to each of the second cutoff frequency of the first peripheral region ER1 and the third cutoff frequency of the second peripheral region ER2.

Alternatively, when the thickness of the piezoelectric layer PL is 1, the thickness of the first electrode LE and the second electrode UE may be about 0.4 to about 0.6, and more specifically, the thickness of the first electrode LE and the second electrode UE may be about 0.529. The thickness of the first auxiliary layer IML1 and the second auxiliary layer IML2 may be from about 0.6 to about 0.8, and more specifically, may be about 0.765. In this case, the ratio (Fc1) of the second cutoff frequency of the first peripheral region ER1 to the first cutoff frequency of the active region AR of the resonant portion 200 and the ratio (Fc2) of the third cutoff frequency of the second peripheral region ER2 to the first cutoff frequency of the active region AR may be from about 0.9 to about 1.1, and more specifically, may be about 0.935.

Alternatively, when the thickness of the piezoelectric layer PL is 1, the thickness of the first electrode LE and the second electrode UE may be about 0.2 to about 0.4, and more specifically, the thickness of the first electrode LE and the second electrode UE may be about 0.313, and the thickness of the first auxiliary layer IML1 and the second auxiliary layer IML2 may be from about 0.5 to about 0.7, and more specifically, from about 0.583 to about 0.652. In this case, the ratio (Fc1) of the second cutoff frequency of the first peripheral region ER1 to the first cutoff frequency of the active region AR of the resonant portion 200 and the ratio (Fc2) of the third cutoff frequency of the second peripheral region ER2 to the first cutoff frequency of the active region AR may be from about 0.9 to about 1.1.

Thus, according to the bulk acoustic resonator 102 according to the present embodiment, the first cutoff frequency of the active region AR may be substantially equal to the second cutoff frequency of the first peripheral region ER1 and the third cutoff frequency of the second peripheral region ER2, so that the acoustic impedance of the active region AR may be substantially equal to the acoustic impedance of the first peripheral region ER1 and the acoustic impedance of the second peripheral region ER2, and lateral waves generated in the active region AR and propagating outwardly may not be reflected back into the active region AR from the first peripheral region ER1 and the second peripheral region ER2. This reduces the resonant energy of the active region AR from being reduced by unnecessarily amplified lateral waves.

Many of the features of the bulk acoustic resonators 100 and 101 according to the previously described embodiments are also applicable to the bulk acoustic resonator 102 according to the present embodiment.

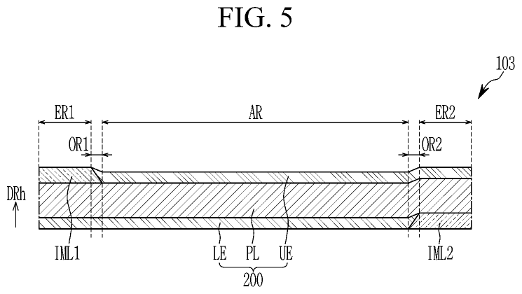

FIG. 5 is a cross-sectional view schematically illustrating a bulk acoustic resonator according to another embodiment.

Referring to FIG. 5, a bulk acoustic resonator 103 includes a resonant portion 200, a first auxiliary layer IML1, and a second auxiliary layer IML2. A substrate 110, an insulating layer 120, a cavity 131, and other elements shown in FIG. 2 are omitted from FIG. 5. The features of the configurations according to the embodiments described with reference to FIG. 2 are applicable to all configurations not illustrated in FIG. 5.

Referring to FIG. 5, the bulk acoustic resonator 103 according to the present embodiment is similar to the bulk acoustic resonators 100, 101, and 102 according to the previously described embodiments. Specific descriptions of the same components are omitted.

As illustrated in FIG. 5, the bulk acoustic resonator 103 according to the present embodiment may include a resonant portion 200 including a first electrode LE, a piezoelectric layer PL, a second electrode UE, a first auxiliary layer IML1, and a second auxiliary layer IML2.

The resonant portion 200 may include an active region AR in which the first electrode LE, the piezoelectric layer PL, and the second electrode UE overlap each other in the height direction DRh. The active region AR may be a portion in which the thicknesses of the first electrode LE, the piezoelectric layer PL, and the second electrode UE overlapping each other in the height direction DRh are substantially constant.

Peripheral regions ER1 and ER2 disposed adjacent to an edge of the active region AR may include a first peripheral region ER1 in which the first electrode LE extending outwardly from the active region AR and not overlapping the second electrode UE in the height direction DRh is disposed, and a second peripheral region ER2 in which the second electrode UE extending outwardly from the active region AR and not overlapping the first electrode LE in the height direction DRh is disposed.

The first auxiliary layer IML1 may be disposed in the first peripheral region ER1, and the second auxiliary layer IML2 may be disposed in the second peripheral region ER2.

The first auxiliary layer IML1 may be disposed at a lateral surface of an edge of the second electrode UE, and the second auxiliary layer IML2 may be disposed at a lateral surface of an edge of the first electrode LE, but the present disclosure is not limited to, and either one or both of the first auxiliary layer IML1 and the second auxiliary layer IML2 may be disposed at a different location.

The first auxiliary layer IML1 and the second auxiliary layer IML2 may include an insulating layer. The first auxiliary layer IML1 and the second auxiliary layer IML2 may include at least some of the materials that the piezoelectric layer PL includes.

The first auxiliary layer IML1 and the second auxiliary layer IML2 may include, but are not limited to, silicon dioxide SiO₂.

The first peripheral region ER1 may be a region where the first electrode LE, the piezoelectric layer PL, and the first auxiliary layer IML1 overlap each other in the height direction DRh, and the second peripheral region ER2 may be a region where the second auxiliary layer IML2, the piezoelectric layer PL, and the second electrode UE overlap each other in the height direction DRh.

A first boundary region OR1 where the end of the second electrode UE overlaps the end of the first auxiliary layer IML1 and a second boundary region OR2 where the end of the first electrode LE overlaps the end of the second auxiliary layer IML2 may be disposed between the active region AR and the peripheral regions ER1 and ER2.

However, according to the bulk acoustic resonator 103 according to the present embodiment, unlike the bulk acoustic resonators 100, 101, and 102 according to the previously described embodiments, the tapered end of the second electrode UE may be disposed above the tapered end of the first auxiliary layer IML1 in the first boundary region OR1, and the tapered end of the first electrode LE may be disposed above the tapered end of the second auxiliary layer IML2 in the second boundary region OR2.

Due to the difference in thickness of the first electrode LE and the second auxiliary layer IML2 in the second boundary region OR2, the piezoelectric layer PL may include a portion having a different surface height along the surface of the first electrode LE and the second auxiliary layer IML2.

A first cutoff frequency of the active region AR of the resonant portion 200 and a second cutoff frequency of the first peripheral region ER1 may be substantially equal to each other. The ratio (Fc1) of the second cutoff frequency to the first cutoff frequency may be from about 0.9 to about 1.1. More specifically, the ratio (Fc1) of the second cutoff frequency to the first cutoff frequency may be from about 0.935 to about 1. Furthermore, the first cutoff frequency of the active region AR and a third cutoff frequency of the second peripheral region ER2 may be substantially equal to each other. The ratio (Fc2) of the third cutoff frequency to the first cutoff frequency may be from about 0.9 to about 1.1. More specifically, the ratio (Fc2) of the third cutoff frequency to the first cutoff frequency may be from about 0.935 to about 1.

The first electrode LE and the second electrode UE include molybdenum (Mo), the piezoelectric layer PL includes aluminum nitride AlN, and the first auxiliary layer IML1 and the second auxiliary layer IML2 include silicon dioxide SiO₂, and when the thickness of the piezoelectric layer PL is 1, the thickness of the first electrode LE and the second electrode UE may be from about 0.4 to about 0.6, and more specifically, about 0.529, and the thickness of the first auxiliary layer IML1 and the second auxiliary layer IML2 may be from about 0.6 to about 0.8, and more specifically, from about 0.693 to about 0.765.

More specifically, when the thickness of the piezoelectric layer PL is 1, the thickness of the first electrode LE and the second electrode UE may be from about 0.4 to about 0.6, and more specifically, the thickness of the first electrode LE and the second electrode UE may be about 0.529. When the thickness of the piezoelectric layer PL is 1, the thickness of the first auxiliary layer IML1 and the second auxiliary layer IML2 may be about 0.6 to about 0.8, and more specifically, the thickness of the first auxiliary layer IML1 and the second auxiliary layer IML2 may be about 0.693. In this case, the first cutoff frequency of the active region AR of the resonant portion 200 and the second cutoff frequency of the first peripheral region ER1 and the third cutoff frequency of the second peripheral region ER2 may be substantially equal to each other.

Alternatively, when the thickness of the piezoelectric layer PL is 1, the thickness of the first electrode LE and the second electrode UE may be about 0.4 to about 0.6, and more specifically, the thickness of the first electrode LE and the second electrode UE may be about 0.529. The thickness of the first auxiliary layer IML1 and the second auxiliary layer IML2 may be from about 0.6 to about 0.8, and more specifically, may be about 0.765. In this case, the ratio (Fc1) of the second cutoff frequency of the first peripheral region ER1 and to the first cutoff frequency of the active region AR of the resonant portion 200 and the ratio (Fc2) of the third cutoff frequency of the second peripheral region ER2 to the first cutoff frequency of the active region AR may be from about 0.9 to about 1.1, and more specifically, may be about 0.935.

Alternatively, when the thickness of the piezoelectric layer PL is 1, the thickness of the first electrode LE and the second electrode UE may be about 0.2 to about 0.4, and more specifically, the thickness of the first electrode LE and the second electrode UE may be about 0.313, and the thickness of the first auxiliary layer IML1 and the second auxiliary layer IML2 may be from about 0.5 to about 0.7, and more specifically, from about 0.583 to about 0.652. In this case, the ratio (Fc1) of the second cutoff frequency of the first peripheral region ER1 to the first cutoff frequency of the active region AR of the resonant portion 200 and the ratio (Fc2) of the third cutoff frequency of the second peripheral region ER2 to the first cutoff frequency of the active region AR may be from about 0.9 to about 1.1.

Thus, according to the bulk acoustic resonator 103 according to the present embodiment, the first cutoff frequency of the active region AR may be substantially equal to the second cutoff frequency of the first peripheral region ER1 and the third cutoff frequency of the second peripheral region ER2, so that the acoustic impedance of the active region AR may be substantially equal to the acoustic impedance of the first peripheral region ER1 and the acoustic impedance of the second peripheral region ER2, and lateral waves generated in the active region AR and propagating outwardly may not be reflected back into the active region AR from the first peripheral region ER1 and the second peripheral region ER2. This reduces the resonant energy of the active region AR from being reduced by unnecessarily amplified lateral waves.

Furthermore, according to the bulk acoustic resonator 103 according to the present embodiment, the end of the thickness-varying tapered second electrode UE disposed in the first boundary region OR1 may overlap the end of the tapered first auxiliary layer IML1, and the end of the tapered first electrode LE disposed in the second boundary region OR2 may overlap the end of the tapered second auxiliary layer IML2. Therefore, the change in the acoustic impedance in the first boundary region OR1 and the second boundary region OR2, where the end of the second electrode UE and the end of the first electrode LE, whose thickness varies, are disposed, may be reduced. Thereby the lateral waves may be prevented from being reflected in the first boundary region OR1 and the second boundary region OR2 and propagated back to the active region AR.

Many of the features of the bulk acoustic resonators 100, 101, and 102 according to the previously described embodiments are also applicable to the bulk acoustic resonator 103 according to the present embodiment.

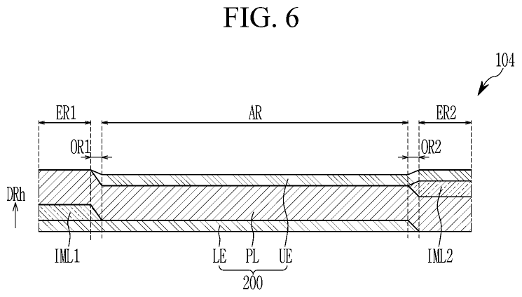

FIG. 6 is a cross-sectional view schematically illustrating a bulk acoustic resonator according to another embodiment.

Referring to FIG. 6, a bulk acoustic resonator 104 includes a resonant portion 200, a first auxiliary layer IML1, and a second auxiliary layer IML2. A substrate 110, an insulating layer 120, a cavity 131, and other elements shown in FIG. 2 are omitted from FIG. 6. The features of the configurations according to the embodiments described with reference to FIG. 2 are applicable to all configurations not illustrated in FIG. 6.

Referring to FIG. 6, the bulk acoustic resonator 104 according to the present embodiment is similar to the bulk acoustic resonators 100, 101, 102, and 103 according to the previously described embodiments. Specific descriptions of the same components are omitted.

As illustrated in FIG. 6, the bulk acoustic resonator 104 according to the present embodiment may include a resonant portion 200 including a first electrode LE, a piezoelectric layer PL, a second electrode UE, a first auxiliary layer IML1, and a second auxiliary layer IML2.

The resonant portion 200 may include an active region AR in which the first electrode LE, the piezoelectric layer PL, and the second electrode UE overlap each other in the height direction DRh. The active region AR may be a portion in which the thicknesses of the first electrode LE, the piezoelectric layer PL, and the second electrode UE overlapping each other are substantially constant.

Peripheral regions ER1 and ER2 disposed adjacent to an edge of the active region AR may include a first peripheral region ER1 in which the first electrode LE extending outwardly from the active region AR and not overlapping the second electrode UE in the height direction DRh is disposed, and a second peripheral region ER2 in which the second electrode UE extending outwardly from the active region AR and not overlapping the first electrode LE in the height direction DRh is disposed.

The first auxiliary layer IML1 may be disposed in the first peripheral region ER1, and the second auxiliary layer IML2 may be disposed in the second peripheral region ER2.

The first peripheral region ER1 may be a region where the first electrode LE, the piezoelectric layer PL, and the first auxiliary layer IML1 overlap each other in the height direction DRh, and the second peripheral region ER2 may be a region where the second auxiliary layer IML2, the piezoelectric layer PL, and the second electrode UE overlap each other in the height direction DRh.

However, according to the bulk acoustic resonator 104 according to the present embodiment, unlike the bulk acoustic resonators 100, 101, 102, and 103 according to the previously described embodiments, the first auxiliary layer IML1 may be disposed between the first electrode LE and the piezoelectric layer PL rather than on the lateral surface of the edge of the second electrode UE, and the second auxiliary layer IML2 may be disposed between the piezoelectric layer PL and the second electrode UE rather than on the lateral surface of the edge of the first electrode LE. However, the present disclosure is not limited thereto, and either one or both of the first auxiliary layer IML1 and the second auxiliary layer IML2 may be disposed at a different location. The first auxiliary layer IML1 may be in contact with the first electrode LE, and the second auxiliary layer IML2 may be in contact with the second electrode UE.

The first auxiliary layer IML1 and the second auxiliary layer IML2 may include an insulating layer. The first auxiliary layer IML1 and the second auxiliary layer IML2 may include at least some of the materials that the piezoelectric layer PL includes. Furthermore, the first auxiliary layer IML1 and the second auxiliary layer IML2 may include a conductive material.

The first auxiliary layer IML1 and the second auxiliary layer IML2 may include, but are not limited to, silicon dioxide SiO₂.

Due to the first auxiliary layer IML1 disposed in the first peripheral region ER1 and the first electrode LE not disposed in the second peripheral region ER2, the piezoelectric layer PL may include a portion having a different surface height along the surface of the first auxiliary layer IML1 and the first electrode LE.

A first boundary region OR1 where the end of the second electrode UE overlaps the end of the first auxiliary layer IML1 in the height direction DRh and a second boundary region OR2 where the end of the first electrode LE overlaps the end of the second auxiliary layer IML2 in the height direction DRh may be disposed between the active region AR and the peripheral regions ER1 and ER2.

A first cutoff frequency of the active region AR of the resonant portion 200 and a second cutoff frequency of the first peripheral region ER1 may be substantially equal to each other. The ratio (Fc1) of the second cutoff frequency to the first cutoff frequency may be from about 0.9 to about 1.1. More specifically, the ratio (Fc1) of the second cutoff frequency to the first cutoff frequency may be from about 0.935 to about 1. Furthermore, the first cutoff frequency of the active region AR and a third cutoff frequency of the second peripheral region ER2 may be substantially equal to each other. The ratio (Fc2) of the third cutoff frequency to the first cutoff frequency may be from about 0.9 to about 1.1. More specifically, the ratio (Fc2) of the third cutoff frequency to the first cutoff frequency may be from about 0.935 to about 1.

The first electrode LE and the second electrode UE include molybdenum (Mo), the piezoelectric layer PL includes aluminum nitride AlN, and the first auxiliary layer IML1 and the second auxiliary layer IML2 include silicon dioxide SiO₂, and when the thickness of the piezoelectric layer PL is 1, the thickness of the first electrode LE and the second electrode UE may be from about 0.4 to about 0.6, and more specifically, about 0.529, and the thickness of the first auxiliary layer IML1 and the second auxiliary layer IML2 may be from about 0.2 to about 0.4, and more specifically, from about 0.257 to about 0.305.

More specifically, when the thickness of the piezoelectric layer PL is 1, the thickness of the first electrode LE and the second electrode UE may be from about 0.4 to about 0.6, and more specifically, the thickness of the first electrode LE and the second electrode UE may be about 0.529. When the thickness of the piezoelectric layer PL is 1, the thickness of the first auxiliary layer IML1 and the second auxiliary layer IML2 may be about 0.2 to about 0.4, and more specifically, about 0.257. In this case, the first cutoff frequency of the active region AR of the resonant portion 200 and the second cutoff frequency of the first peripheral region ER1 and the third cutoff frequency of the second peripheral region ER2 may be substantially equal to each other.

Alternatively, when the thickness of the piezoelectric layer PL is 1, the thickness of the first electrode LE and the second electrode UE may be about 0.4 to about 0.6, and more specifically, the thickness of the first electrode LE and the second electrode UE may be about 0.529. The thickness of the first auxiliary layer IML1 and the second auxiliary layer IML2 may be from about 0.2 to about 0.4, and more specifically, may be about 0.305. In this case, the ratio (Fc1) of the second cutoff frequency of the first peripheral region ER1 to the first cutoff frequency of the active region AR of the resonant portion 200 and the ratio (Fc2) of the third cutoff frequency of the second peripheral region ER2 to the first cutoff frequency of the active region AR may be from about 0.9 to about 1.1, and more specifically, may be about 0.935.

Alternatively, when the thickness of the piezoelectric layer PL is 1, the thickness of the first electrode LE and the second electrode UE may be about 0.2 to about 0.4, and more specifically, the thickness of the first electrode LE and the second electrode UE may be about 0.313, and the thickness of the first auxiliary layer IML1 and the second auxiliary layer IML2 may be from about 0.1 to about 0.3, and more specifically, from about 0.166 to about 0.204. In this case, the ratio (Fc1) of the second cutoff frequency of the first peripheral region ER1 to the first cutoff frequency of the active region AR of the resonant portion 200 and the ratio (Fc2) of the third cutoff frequency of the second peripheral region ER2 to the first cutoff frequency of the active region AR may be from about 0.9 to about 1.1.

Thus, according to the bulk acoustic resonator 104 according to the present embodiment, the first cutoff frequency of the active region AR may be substantially equal to the second cutoff frequency of the first peripheral region ER1 and the third cutoff frequency of the second peripheral region ER2, so that the acoustic impedance of the active region AR may be substantially equal to the acoustic impedance of the first peripheral region ER1 and the acoustic impedance of the second peripheral region ER2, and lateral waves generated in the active region AR and propagating outwardly may not be reflected back into the active region AR from the first peripheral region ER1 and the second peripheral region ER2. This reduces the resonant energy of the active region AR from being reduced by unnecessarily amplified lateral waves.

Furthermore, according to the bulk acoustic resonator 104 according to the present embodiment, the end of the thickness-varying tapered second electrode UE disposed in the first boundary region OR1 may overlap the end of the tapered first auxiliary layer IML1 in the height direction DRh, and the end of the tapered first electrode LE disposed in the second boundary region OR2 may overlap the end of the tapered second auxiliary layer IML2 in the height direction DRh. Therefore, the change in acoustic impedance in the first boundary region OR1 and the second boundary region OR2, where the end of the second electrode UE and the end of the first electrode LE, whose thickness varies, are disposed, may be reduced, thereby preventing lateral waves from being reflected and propagated back to the active region AR in the first boundary region OR1 and the second boundary region OR2.

Many of the features of the bulk acoustic resonators 100, 101, 102, and 103 according to the previously described embodiments are also applicable to the bulk acoustic resonator 104 according to the present embodiment.

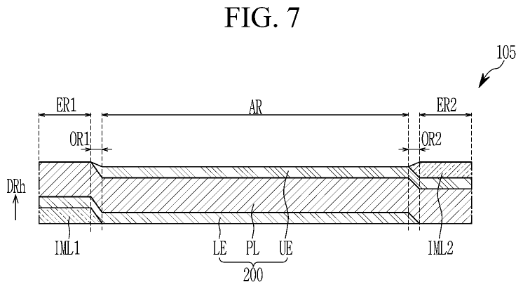

FIG. 7 is a cross-sectional view schematically illustrating a bulk acoustic resonator according to another embodiment.

Referring to FIG. 7, a bulk acoustic resonator 105 includes a resonant portion 200, a first auxiliary layer IML1, and a second auxiliary layer IML2. A substrate 110, an insulating layer 120, a cavity 131, and other elements shown in FIG. 2 are omitted from FIG. 7. The features of the configurations according to the embodiments described with reference to FIG. 2 are applicable to all configurations not illustrated in FIG. 7.

Referring to FIG. 7, the bulk acoustic resonator 105 according to the present embodiment is similar to the bulk acoustic resonators 100, 101, 102, 103, and 104 according to the previously described embodiments. Specific descriptions of the same components are omitted.

As illustrated in FIG. 7, the bulk acoustic resonator 105 according to the present embodiment may include a resonant portion 200 including a first electrode LE, a piezoelectric layer PL, a second electrode UE, a first auxiliary layer IML1, and a second auxiliary layer IML2.

The resonant portion 200 may include an active region AR in which the first electrode LE, the piezoelectric layer PL, and the second electrode UE overlap each other in the height direction DRh. The active region AR may be a portion in which the thicknesses of the first electrode LE, the piezoelectric layer PL, and the second electrode UE overlapping each other in the height direction Dh are substantially constant.

Peripheral regions ER1 and ER2 disposed adjacent to an edge of the active region AR may include a first peripheral region ER1 in which the first electrode LE extending outwardly from the active region AR and not overlapping the second electrode UE in the height direction DRh is disposed, and a second peripheral region ER2 in which the second electrode UE extending outwardly from the active region AR and not overlapping the first electrode LE in the height direction DRh is disposed.

The first auxiliary layer IML1 may be disposed in the first peripheral region ER1, and the second auxiliary layer IML2 may be disposed in the second peripheral region ER2.

The first peripheral region ER1 may be a region where the first electrode LE, the piezoelectric layer PL, and the first auxiliary layer IML1 overlap each other in the height direction DRh, and the second peripheral region ER2 may be a region where the second auxiliary layer IML2, the piezoelectric layer PL, and the second electrode UE overlap each other in the height direction DRh.

However, according to the bulk acoustic resonator 105 according to the present embodiment, unlike the bulk acoustic resonators 100, 101, 102, 103, and 104 according to the previously described embodiments, the first auxiliary layer IML1 may be disposed under the first electrode LE rather than on the lateral surface of the edge of the second electrode UE, and the second auxiliary layer IML2 may be disposed on the second electrode UE rather than on the lateral surface of the edge of the first electrode LE. However, the present disclosure is not limited thereto, and either one or both of the first auxiliary layer IML1 and the second auxiliary layer IML2 may be disposed at a different location. The first auxiliary layer IML1 may be in contact with the first electrode LE, and the second auxiliary layer IML2 may be in contact with the second electrode UE.

The first auxiliary layer IML1 and the second auxiliary layer IML2 may include an insulating material. The first auxiliary layer IML1 and the second auxiliary layer IML2 may include at least some of the materials that the piezoelectric layer PL includes. Furthermore, the first auxiliary layer IML1 and the second auxiliary layer IML2 may include a conductive material.

The first auxiliary layer IML1 and the second auxiliary layer IML2 may include, but are not limited to, silicon dioxide SIO₂.

Due to a step of the first auxiliary layer IML1 disposed in the first peripheral region ER1, the first electrode LE and the piezoelectric layer PL disposed on the first auxiliary layer IML1 may include a portion in which a height varies along the surface of the first auxiliary layer IML1 in the first boundary region OR1. Due to the first electrode LE not being disposed in the second peripheral region ER2, the piezoelectric layer PL and the second electrode UE disposed on the first electrode LE may include a portion in which a surface height varies in the second boundary region OR2.

A first boundary region OR1 where the end of the second electrode UE overlaps the end of the first auxiliary layer IML1 in the height direction DRh and a second boundary region OR2 where the end of the first electrode LE overlaps the end of the second auxiliary layer IML2 in the height direction DRh may be disposed between the active region AR and the peripheral regions ER1 and ER2.

A first cutoff frequency of the active region AR of the resonant portion 200 and a second cutoff frequency of the first peripheral region ER1 may be substantially equal to each other. The ratio (Fc1) of the second cutoff frequency to the first cutoff frequency may be from about 0.9 to about 1.1. More specifically, the ratio (Fc1) of the second cutoff frequency to the first cutoff frequency may be from about 0.935 to about 1. Furthermore, the first cutoff frequency of the active region AR and a third cutoff frequency of the second peripheral region ER2 may be substantially equal to each other. The ratio (Fc2) of the third cutoff frequency to the first cutoff frequency may be from about 0.9 to about 1.1. More specifically, the ratio (Fc2) of the third cutoff frequency to the first cutoff frequency may be from about 0.935 to about 1.

The first electrode LE and the second electrode UE include molybdenum (Mo), the piezoelectric layer PL includes aluminum nitride AlN, and the first auxiliary layer IML1 and the second auxiliary layer IML2 include silicon dioxide SiO₂, and when the thickness of the piezoelectric layer PL is 1, the thickness of the first electrode LE and the second electrode UE may be from about 0.4 to about 0.6, and more specifically, about 0.529, and the thickness of the first auxiliary layer IML1 and the second auxiliary layer IML2 may be from about 0.7 to about 0.9, and more specifically, from about 0.798 to about 0.866.

More specifically, when the thickness of the piezoelectric layer PL is 1, the thickness of the first electrode LE and the second electrode UE may be from about 0.4 to about 0.6, and more specifically, the thickness of the first electrode LE and the second electrode UE may be about 0.529. When the thickness of the piezoelectric layer PL is 1, the thickness of the first auxiliary layer IML1 and the second auxiliary layer IML2 may be about 0.7 to about 0.9, and more specifically, about 0.798. In this case, the first cutoff frequency of the active region AR of the resonant portion 200 and the second cutoff frequency of the first peripheral region ER1 and the third cutoff frequency of the second peripheral region ER2 may be substantially equal to each other.

Alternatively, when the thickness of the piezoelectric layer PL is 1, the thickness of the first electrode LE and the second electrode UE may be about 0.4 to about 0.6, and more specifically, the thickness of the first electrode LE and the second electrode UE may be about 0.529. The thickness of the first auxiliary layer IML1 and the second auxiliary layer IML2 may be from about 0.7 to about 0.9, and more specifically, may be about 0.866. In this case, the ratio (Fc1) of the second cutoff frequency of the first peripheral region ER1 to the first cutoff frequency of the active region AR of the resonant portion 200 and the ratio (Fc2) of the third cutoff frequency of the second peripheral region ER2 to the first cutoff frequency of the active region AR may be from about 0.9 to about 1.1, and more specifically, may be about 0.935.

Alternatively, when the thickness of the piezoelectric layer PL is 1, the thickness of the first electrode LE and the second electrode UE may be about 0.2 to about 0.4, and more specifically, the thickness of the first electrode LE and the second electrode UE may be about 0.313, and the thickness of the first auxiliary layer IML1 and the second auxiliary layer IML2 may be from about 0.6 to about 0.8, and more specifically, from about 0.691 to about 0.753. In this case, the ratio (Fc1) of the second cutoff frequency of the first peripheral region ER1 to the first cutoff frequency of the active region AR of the resonant portion 200 and the ratio (Fc2) of the third cutoff frequency of the second peripheral region ER2 to the first cutoff frequency of the active region AR may be from about 0.9 to about 1.1.

Thus, according to the bulk acoustic resonator 105 according to the present embodiment, the first cutoff frequency of the active region AR may be substantially equal to the second cutoff frequency of the first peripheral region ER1 and the third cutoff frequency of the second peripheral region ER2, so that the acoustic impedance of the active region AR may be substantially equal to the acoustic impedance of the first peripheral region ER1 and the acoustic impedance of the second peripheral region ER2, and lateral waves generated in the active region AR and propagating outwardly may not be reflected back into the active region AR from the first peripheral region ER1 and the second peripheral region ER2. This reduces the resonant energy of the active region AR from being reduced by unnecessarily amplified lateral waves.

Furthermore, according to the bulk acoustic resonator 105 according to the present embodiment, the end of the thickness-varying tapered second electrode UE disposed in the first boundary region OR1 may overlap the end of the tapered first auxiliary layer IML1 in the height direction DRh, and the end of the tapered first electrode LE disposed in the second boundary region OR2 may overlap the end of the tapered second auxiliary layer IML2 in the height direction Dh. Therefore, the change in the acoustic impedance in the first boundary region OR1 and the second boundary region OR2, where the end of the second electrode UE and the end of the first electrode LE, whose thickness varies, are disposed, may be reduced, thereby preventing the lateral waves from being reflected in the first boundary region OR1 and the second boundary region OR2 and propagated back to the active region AR.

Many of the features of the bulk acoustic resonators 100, 101, 102, 103, and 104 according to the previously described embodiments are also applicable to the bulk acoustic resonator 105 according to the present embodiment.

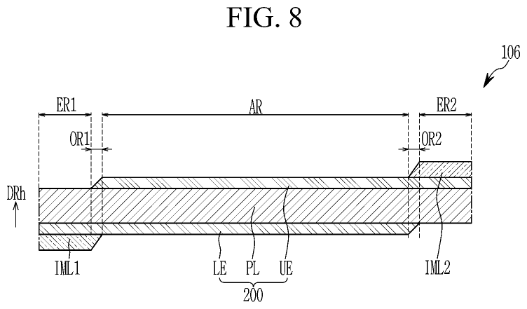

FIG. 8 is a cross-sectional view schematically illustrating a bulk acoustic resonator according to another embodiment.

Referring to FIG. 8, a bulk acoustic resonator 106 includes a resonant portion 200, a first auxiliary layer IML1, and a second auxiliary layer IML2. A substrate 110, an insulating layer 120, a cavity 131, and other elements shown in FIG. 2 are omitted from FIG. 8. The features of the configurations according to the embodiments described with reference to FIG. 2 are applicable to all configurations not illustrated in FIG. 8.

Referring to FIG. 8, the bulk acoustic resonator 106 according to the present embodiment is similar to the bulk acoustic resonators 100, 101, 102, 103, 104, and 105 according to the previously described embodiments. Specific descriptions of the same components are omitted.

As illustrated in FIG. 8, the bulk acoustic resonator 106 according to the present embodiment may include a resonant portion 200 including a first electrode LE, a piezoelectric layer PL, a second electrode UE, a first auxiliary layer IML1, and a second auxiliary layer IML2.

The resonant portion 200 may include an active region AR in which the first electrode LE, the piezoelectric layer PL, and the second electrode UE overlap each other in the height direction DRh. The active region AR may be a portion in which the thicknesses of the first electrode LE, the piezoelectric layer PL, and the second electrode UE overlapping each other in the height direction DRh are substantially constant.

Peripheral regions ER1 and ER2 disposed adjacent to an edge of the active region AR may include a first peripheral region ER1 in which the first electrode LE extending outwardly from the active region AR and not overlapping the second electrode UE in the height direction DRh is disposed, and a second peripheral region ER2 in which the second electrode UE extending outwardly from the active region AR and not overlapping the first electrode LE in the height direction DRh is disposed.

The first auxiliary layer IML1 may be disposed in the first peripheral region ER1, and the second auxiliary layer IML2 may be disposed in the second peripheral region ER2.

The first peripheral region ER1 may be a region where the first electrode LE, the piezoelectric layer PL, and the first auxiliary layer IML1 overlap each other in the height direction DRh, and the second peripheral region ER2 may be a region where the second auxiliary layer IML2, the piezoelectric layer PL, and the second electrode UE overlap each other in the height direction DRh.

However, according to the bulk acoustic resonator 106 according to the present embodiment, unlike the bulk acoustic resonators 100, 101, 102, 103, 104, and 105 according to the previously described embodiments, the first auxiliary layer IML1 may be disposed under the first electrode LE rather than on the lateral surface of the edge of the second electrode UE, and the second auxiliary layer IML2 may be disposed on the second electrode UE rather than on the lateral surface of the edge of the first electrode LE. However, the present disclosure is not limited thereto, and either one or both of the first auxiliary layer IML1 and the second auxiliary layer IML2 may be disposed at a different location. The first auxiliary layer IML1 may be in contact with the first electrode LE, and the second auxiliary layer IML2 may be in contact with the second electrode UE.

Furthermore, according to the bulk acoustic resonator 106 according to the present embodiment, unlike the bulk acoustic resonator 105 according to the previously described embodiment, an extending portion of the first electrode LE overlapping the first auxiliary layer IML1 and an extending portion of the second electrode UE overlapping the second auxiliary layer IML2 may not change in surface height.

The first auxiliary layer IML1 and the second auxiliary layer IML2 may include an insulating material. The first auxiliary layer IML1 and the second auxiliary layer IML2 may include at least some of the materials that the piezoelectric layer PL includes. Furthermore, the first auxiliary layer IML1 and the second auxiliary layer IML2 may include a conductive material.

The first auxiliary layer IML1 and the second auxiliary layer IML2 may include, but are not limited to, silicon dioxide SiO₂.

A first boundary region OR1 where the end of the second electrode UE overlaps the end of the first auxiliary layer IML1 in the height direction DRh and a second boundary region OR2 where the end of the first electrode LE overlaps the end of the second auxiliary layer IML2 in the height direction DRh may be disposed between the active region AR and the peripheral regions ER1 and ER2.

A first cutoff frequency of the active region AR of the resonant portion 200 and a second cutoff frequency of the first peripheral region ER1 may be substantially equal to each other, and more particularly, the ratio (Fc1) of the second cutoff frequency to the first cutoff frequency may be from about 0.9 to about 1.1. More specifically, the ratio (Fc1) of the second cutoff frequency to the first cutoff frequency may be from about 0.935 to about 1. Furthermore, the first cutoff frequency of the active region AR and the third cutoff frequency of the second peripheral region ER2 may be substantially equal to each other, and the ratio (Fc2) of the third cutoff frequency to the first cutoff frequency may be from about 0.9 to about 1.1, and more specifically, from about 0.935 to about 1.

The first electrode LE and the second electrode UE include molybdenum (Mo), the piezoelectric layer PL includes aluminum nitride AlN, and the first auxiliary layer IML1 and the second auxiliary layer IML2 include silicon dioxide SiO₂, and when the thickness of the piezoelectric layer PL is 1, the thickness of the first electrode LE and the second electrode UE may be from about 0.4 to about 0.6, and more specifically, about 0.529, and the thickness of the first auxiliary layer IML1 and the second auxiliary layer IML2 may be from about 0.7 to about 0.9, and more specifically, from about 0.798 to about 0.866.

More specifically, when the thickness of the piezoelectric layer PL is 1, the thickness of the first electrode LE and the second electrode UE may be about 0.4 to about 0.6, and more specifically, the thickness of the first electrode LE and the second electrode UE may be about 0.529, and the thickness of the first auxiliary layer IML1 and the second auxiliary layer IML2 may be from about 0.7 to about 0.9, and more specifically, may be about 0.798, and in this case, the first cutoff frequency of the active region AR, the second cutoff frequency of the first peripheral region ER1, and the third cutoff frequency of the second peripheral region ER2 of the resonant portion 200 may be substantially equal to each other.

Alternatively, when the thickness of the piezoelectric layer PL is 1, the thickness of the first electrode LE and the second electrode UE may be about 0.4 to about 0.6, and more specifically, the thickness of the first electrode LE and the second electrode UE may be about 0.529, and the thickness of the first auxiliary layer IML1 and the second auxiliary layer IML2 may be from about 0.7 to about 0.9, and more specifically, may be about 0.866, and in this case, the ratio (Fc1) of the second cutoff frequency of the first peripheral region ER1 to the first cutoff frequency of the active region AR of the resonant portion 200 and the ratio (Fc2) of the third cutoff frequency of the second peripheral region ER2 to the first cutoff frequency of the active region AR may be from about 0.9 to about 1.1, and more specifically, may be about 0.935.

Alternatively, when the thickness of the piezoelectric layer PL is 1, the thickness of the first electrode LE and the second electrode UE may be about 0.2 to about 0.4, and more specifically, the thickness of the first electrode LE and the second electrode UE may be about 0.313, and the thickness of the first auxiliary layer IML1 and the second auxiliary layer IML2 may be from about 0.6 to about 0.8, and more specifically, from about 0.691 to about 0.753. In this case, the ratio (Fc1) of the second cutoff frequency of the first peripheral region ER1 to the first cutoff frequency of the active region AR of the resonant portion 200 and the ratio (Fc2) of the third cutoff frequency of the second peripheral region ER2 to the first cutoff frequency of the active region AR may be from about 0.9 to about 1.1.

Thus, according to the bulk acoustic resonator 106 according to the present embodiment, the first cutoff frequency of the active region AR may be substantially equal to the second cutoff frequency of the first peripheral region ER1 and the third cutoff frequency of the second peripheral region ER2, so that the acoustic impedance of the active region AR may be substantially equal to the acoustic impedance of the first peripheral region ER1 and the acoustic impedance of the second peripheral region ER2, and lateral waves generated in the active region AR and propagating outwardly may not be reflected back into the active region AR from the first peripheral region ER1 and the second peripheral region ER2. This reduces the resonant energy of the active region AR from being reduced by unnecessarily amplified lateral waves.

Furthermore, according to the bulk acoustic resonator 106 according to the present embodiment, the end of the thickness-varying tapered second electrode UE disposed in the first boundary region OR1 may overlap the end of the tapered first auxiliary layer IML1 in the height direction DRh, and the end of the tapered first electrode LE disposed in the second boundary region OR2 may overlap the end of the tapered second auxiliary layer IML2 in the height direction DRh. Therefore, the change in the acoustic impedance in the first boundary region OR1 and the second boundary region OR2, where the end of the second electrode UE and the end of the first electrode LE, whose thickness varies, are disposed, may be reduced. Thereby the lateral waves may be prevented from being reflected in the first boundary region OR1 and the second boundary region OR2 and propagated back to the active region AR.

Many of the features of the bulk acoustic resonators 100, 101, 102, 103, 104, and 105 according to the previously described embodiments are also applicable to the bulk acoustic resonator 106 according to the present embodiment.

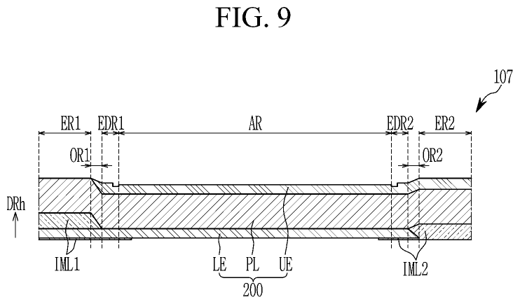

FIG. 9 is a cross-sectional view schematically illustrating a bulk acoustic resonator according to another embodiment.

Referring to FIG. 9, a bulk acoustic resonator 107 includes a resonant portion 200, a first auxiliary layer IML1, and a second auxiliary layer IML2. A substrate 110, an insulating layer 120, a cavity 131, and other elements shown in FIG. 2 are omitted from FIG. 9. The features of the configurations according to the embodiments described with reference to FIG. 2 are applicable to all configurations not illustrated in FIG. 9.

Referring to FIG. 9, the bulk acoustic resonator 107 according to the present embodiment is similar to the bulk acoustic resonators 100, 101, 102, 103, 104, 105, and 106 according to the previously described embodiments. Specific descriptions of the same components are omitted.

As illustrated in FIG. 9, the bulk acoustic resonator 107 according to the present embodiment may include a resonant portion 200 including a first electrode LE, a piezoelectric layer PL, a second electrode UE, a first auxiliary layer IML1, and a second auxiliary layer IML2.

The resonant portion 200 may include an active region AR in which the first electrode LE, the piezoelectric layer PL, and the second electrode UE overlap each other in the height direction DRh. The active region AR may be a portion in which the thicknesses of the first electrode LE, the piezoelectric layer PL, and the second electrode UE overlapping each other in the height direction DRh are substantially constant.

Peripheral regions ER1 and ER2 disposed adjacent to an edge of the active region AR may include a first peripheral region ER1 in which the first electrode LE extending outwardly from the active region AR and not overlapping the second electrode UE in the height direction DRh is disposed, and a second peripheral region ER2 in which the second electrode UE extending outwardly from the active region AR and not overlapping the first electrode LE in the height direction DRh is disposed.

The first auxiliary layer IML1 may be disposed in the first peripheral region ER1, and the second auxiliary layer IML2 may be disposed in the second peripheral region ER2.

The first peripheral region ER1 may be a region where the first electrode LE, the piezoelectric layer PL, and the first auxiliary layer IML1 overlap each other in the height direction DRh, and the second peripheral region ER2 may be a region where the second auxiliary layer IML2, the piezoelectric layer PL, and the second electrode UE overlap each other in the height direction DRh.

However, according to the bulk acoustic resonator 107 according to the present embodiment, unlike the bulk acoustic resonators 100, 101, 102, 103, 104, 105, and 106 according to the previously described embodiments, the first auxiliary layer IML1 may be disposed on and below the first electrode LE rather than on the lateral surface of the edge of the second electrode UE, and the second auxiliary layer IML2 may be disposed on the lateral surface of the edge of the first electrode LE and below the first electrode LE. However, the present disclosure is not limited thereto, and either one or both of the first auxiliary layer IML1 and the second auxiliary layer IML2 may be disposed at a different location. The first auxiliary layer IML1 may be in contact with the first electrode LE, and the second auxiliary layer IML2 may also be in contact with the first electrode LE.

The first auxiliary layer IML1 and the second auxiliary layer IML2 may include an insulating material. The first auxiliary layer IML1 and the second auxiliary layer IML2 may include at least some of the materials that the piezoelectric layer PL includes. Furthermore, the first auxiliary layer IML1 may include a conductive material, while the second auxiliary layer IML2 may have an insulating property.

The first auxiliary layer IML1 and the second auxiliary layer IML2 may include, but are not limited to, silicon dioxide SiO₂.

A first boundary region OR1 where the end of the second electrode UE overlaps the end of the first auxiliary layer IML1 in the height direction DRh and a second boundary region OR2 where the end of the first electrode LE overlaps the end of the second auxiliary layer IML2 may be disposed between the active region AR and the peripheral regions ER1 and ER2.

Furthermore, according to the bulk acoustic resonator 107 according to the present embodiment, unlike the bulk acoustic resonators 100, 101, 102, 103, 104, 105, and 106 according to the previously described embodiments, a first trench portion EDR1 and a second trench portion EDR2 in which a groove is formed in the second electrode UE may be disposed between the active region AR and the boundary regions OR1 and OR2. The thickness of portions of the second electrode UE in the first trench portion EDR1 and the second trench portion EDR2 may be less than the thickness of a portion of the second electrode UE disposed in the active region AR. By reducing the thickness of the portions of the second electrode UE disposed in the first trench portion EDR1 and the second trench portion EDR2, the dispersion characteristics of the resonant portion 200 in the first trench portion EDR1 and the second trench portion EDR2 may change. Thus, the resonant energy within the active region AR of the resonant portion 200 may be reduced from being transferred to the outside.

A first cutoff frequency of the active region AR of the resonant portion 200 and a second cutoff frequency of the first peripheral region ER1 may be substantially equal to each other, and more specifically, a ratio (Fc1) of the second cutoff frequency to the first cutoff frequency may be from about 0.9 to about 1.1, and more specifically, from about 0.935 to about 1. Furthermore, the first cutoff frequency of the active region AR and the third cutoff frequency of the second peripheral region ER2 may be substantially equal to each other, and the ratio (Fc2) of the third cutoff frequency to the first cutoff frequency may be from about 0.9 to about 1.1, and more specifically, from about 0.935 to about 1.

The first electrode LE and the second electrode UE include molybdenum (Mo), the piezoelectric layer PL includes aluminum nitride AlN, and the first auxiliary layer IML1 and the second auxiliary layer IML2 include silicon dioxide SiO₂, and when the thickness of the piezoelectric layer PL is 1, the thickness of the first electrode LE and the second electrode UE may be from about 0.4 to about 0.6, and more specifically, about 0.529, and the thickness of the first auxiliary layer IML1 may be from about 0.2 to about 0.4, and more specifically, from about 0.257 to about 0.305, and the thickness of the second auxiliary layer IML2 may be from about 0.6 to about 0.8, and more specifically, from about 0.693 to about 0.765.

More specifically, when the thickness of the piezoelectric layer PL is 1, the thickness of the first electrode LE and the second electrode UE may be about 0.4 to about 0.6, and more specifically, the thickness of the first electrode LE and the second electrode UE may be about 0.529, the thickness of the first auxiliary layer IML1 may be from about 0.2 to about 0.4, and more specifically, may be about 0.257, and the thickness of the second auxiliary layer IML2 may be from about 0.6 to about 0.8, and more specifically, may be about 0.693, and in this case, the first cutoff frequency of the active region AR, the second cutoff frequency of the first peripheral region ER1, and the third cutoff frequency of the second peripheral region ER2 of the resonant portion 200 may be substantially equal to each other.

Alternatively, when the thickness of the piezoelectric layer PL is 1, the thickness of the first electrode LE and the second electrode UE may be about 0.4 to about 0.6, and more specifically, the thickness of the first electrode LE and the second electrode UE may be about 0.529, the thickness of the first auxiliary layer IML1 may be from about 0.2 to about 0.4, and more specifically, may be about 0.305, and the thickness of the second auxiliary layer IML2 may be from about 0.6 to about 0.8, and more specifically, may be about 0.765, and in this case, the ratio (Fc1) of the second cutoff frequency of the first peripheral region ER1 to the first cutoff frequency of the active region AR of the resonant portion 200 and the ratio (Fc2) of the third cutoff frequency of the second peripheral region ER2 to the first cutoff frequency of the active region AR may be from about 0.9 to about 1.1, and more specifically, may be about 0.935.

Alternatively, when the thickness of the piezoelectric layer PL is 1, the thickness of the first electrode LE and the second electrode UE may be about 0.2 to about 0.4, and more specifically, the thickness of the first electrode LE and the second electrode UE may be about 0.313, the thickness of the first auxiliary layer IML1 may be from about 0.1 to about 0.3, and more specifically, may be from about 0.166 to about 0.204, and the thickness of the second auxiliary layer IML2 may be from about 0.5 to about 0.7, and more specifically, may be from about 0.583 to about 0.652, and in this case, the ratio (Fc1) of the second cutoff frequency of the first peripheral region ER1 to the first cutoff frequency of the active region AR of the resonant portion 200 and the ratio (Fc2) of the third cutoff frequency of the second peripheral region ER2 to the first cutoff frequency of the active region AR may be from about 0.9 to about 1.1.

Thus, according to the bulk acoustic resonator 107 according to the present embodiment, the first cutoff frequency of the active region AR may be substantially equal to the second cutoff frequency of the first peripheral region ER1 and the third cutoff frequency of the second peripheral region ER2, so that the acoustic impedance of the active region AR may be substantially equal to the acoustic impedance of the first peripheral region ER1 and the acoustic impedance of the second peripheral region ER2, and lateral waves generated in the active region AR and propagating outwardly may not be reflected back into the active region AR from the first peripheral region ER1 and the second peripheral region ER2. This reduces the resonant energy of the active region AR from being reduced by unnecessarily amplified lateral waves.

Furthermore, according to the bulk acoustic resonator 107 according to the present embodiment, the end of the thickness-varying tapered second electrode UE disposed in the first boundary region OR1 may overlap the end of the tapered first auxiliary layer IML1 in the height direction, and the end of the tapered first electrode LE disposed in the second boundary region OR2 may overlap the end of the tapered second auxiliary layer IML2. Therefore, the change in the acoustic impedance in the first boundary region OR1 and the second boundary region OR2, where the end of the second electrode UE and the end of the first electrode LE, whose thickness varies, are disposed, may be reduced. Thereby the lateral waves may be prevented from being reflected in the first boundary region OR1 and the second boundary region OR2 and propagated back to the active region AR.

Furthermore, according to the bulk acoustic resonator 107 according to the present embodiment, extending portions of the first auxiliary layer IML1 and the second auxiliary layer IML2 may also be disposed under the portions of the first electrode LE disposed in the first trench portion EDR1 and the second trench portion EDR2 where the thickness of the second electrode UE decreases. The thickness of the extending portions of the first auxiliary layer IML1 and the second auxiliary layer IML2 disposed in the first trench portion EDR1 and the second trench portion EDR2 may be less than the thickness of the remaining portions of the first auxiliary layer IML1 and the second auxiliary layer IML2. Similarly, the extending portions of the first auxiliary layer IML1 and the second auxiliary layer IML2 are disposed in the first trench portion EDR1 and the second trench portion EDR2, and the change in the acoustic impedance even in the first trench portion EDR1 and the second trench portion EDR2 where the thickness of the second electrode UE changes may be reduced, thereby preventing lateral waves from being reflected from the first trench portion EDR1 and the second trench portion EDR2 and propagating back to the active region AR.

Many of the features of the bulk acoustic resonators 100, 101, 102, 103, 104, 105, and 106 according to the previously described embodiments are also applicable to the bulk acoustic resonator 107 according to the present embodiment.

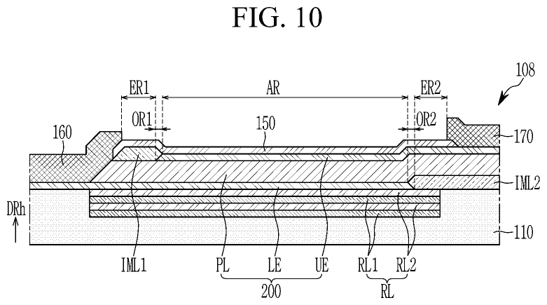

FIG. 10 is a cross-sectional view schematically illustrating a bulk acoustic resonator according to another embodiment.

Referring to FIG. 10, a bulk acoustic resonator 108 according to the present embodiment is similar to the bulk acoustic resonator 100 according to the embodiment described with reference to FIG. 2. Specific descriptions of the same components are omitted.

As illustrated in FIG. 10, the bulk acoustic resonator 108 according to the present embodiment may include a resonant portion 200 including a first electrode LE, a piezoelectric layer PL, a second electrode UE, a first auxiliary layer IML1, and a second auxiliary layer IML2.

The resonant portion 200 may include an active region AR in which the first electrode LE, the piezoelectric layer PL, and the second electrode UE overlap each other in the height direction DRh. The active region AR may be a portion in which the thicknesses of the first electrode LE, the piezoelectric layer PL, and the second electrode UE overlapping each other in the height direction DRh are substantially constant.

Peripheral regions ER1 and ER2 disposed adjacent to an edge of the active region AR may include a first peripheral region ER1 in which the first electrode LE extending outwardly from the active region AR and not overlapping the second electrode UE in the height direction DRh is disposed, and a second peripheral region ER2 in which the second electrode UE extending outwardly from the active region AR and not overlapping the first electrode LE in the height direction DRh is disposed.

The first auxiliary layer IML1 may be disposed in the first peripheral region ER1, and the second auxiliary layer IML2 may be disposed in the second peripheral region ER2.

The first auxiliary layer IML1 may be disposed at a lateral surface of an edge of the second electrode UE, and the second auxiliary layer IML2 may be disposed at a lateral surface of an edge of the first electrode LE, but the present disclosure is not limited to, and either one or both of the first auxiliary layer IML1 and the second auxiliary layer IML2 may be disposed at a different location.

The first auxiliary layer IML1 and the second auxiliary layer IML2 may include an insulating material. The first auxiliary layer IML1 and the second auxiliary layer IML2 may include at least some of the materials that the piezoelectric layer PL includes.

The first auxiliary layer IML1 and the second auxiliary layer IML2 may include, but are not limited to, silicon dioxide SiO₂.

However, the bulk acoustic resonator 108 according to the present embodiment, unlike the bulk acoustic resonator 100 according to the embodiment previously described with reference to FIG. 2, may not include a cavity 131 and may instead include an acoustic reflector layer RL, such as a Bragg reflector layer. The acoustic reflector layer RL may be disposed inside the substrate 110, and may include a plurality of first acoustic reflector layers RL1 and a plurality of second acoustic reflector layers RL2 alternately stacked to overlap the resonant portion 200 in the height direction DRh from below the resonant portion 200. The first acoustic reflector layer RL1 may be a layer having a relatively high acoustic impedance, and the second acoustic reflector layer RL2 may be a layer having a relatively low acoustic impedance.

The first acoustic reflector layer RL1 may have a higher density than the second acoustic reflector layer RL2. For example, the first acoustic reflector layer RL1 may include any one or any combination of any two or more of tungsten (W), molybdenum (Mo), ruthenium (Ru), iridium (Ir), tantalum (Ta), platinum (Pt), and copper (Cu). The second acoustic reflector layer RL2 may have a lower density than the first acoustic reflector layer RL1. For example, the second acoustic reflector layer RL2 may include any one or any combination of any two or more of silicon dioxide (SiO₂), silicon nitride (Si₃N₄), and aluminum nitride (AlN). However, the first acoustic reflector layer RL1 and the second acoustic reflector layer RL2 are not limited thereto.

The acoustic reflector layer RL may reflect acoustic waves toward the resonant portion 200 in a direction perpendicular to the surface of the substrate 110, thereby preventing acoustic waves from escaping to the underside of the substrate 110.

The first peripheral region ER1 may be a region where the first electrode LE, the piezoelectric layer PL, and the first auxiliary layer IML1 overlap each other in the height direction DRh, and the second peripheral region ER2 may be a region where the second auxiliary layer IML2, the piezoelectric layer PL, and the second electrode UE overlap each other in the height direction DRh.

The dispersion characteristics of the lateral waves in the active region AR of the bulk acoustic resonator 100 according to the embodiment illustrated in FIG. 2 and the lateral waves in the active region AR of the bulk acoustic resonator 108 according to the present embodiment are inverse to each other, and the cutoff frequencies may also be inversely related.

According to the bulk acoustic resonator 108 according to the present embodiment, a first cutoff frequency of the active region AR and a second cutoff frequency of the first peripheral region ER1 may be substantially equal to each other, and more specifically, the ratio (Fc1) of the second cutoff frequency to the first cutoff frequency may be from about 0.9 to about 1.1, and more specifically, from about 1 to about 1.069. Furthermore, the first cutoff frequency of the active region AR and the third cutoff frequency of the second peripheral region ER2 may be substantially equal to each other, and the ratio (Fc2) of the third cutoff frequency to the first cutoff frequency may be from about 0.9 to about 1.1, and more specifically, from about 1 to about 1.069.

Thus, according to the bulk acoustic resonator 108 according to the present embodiment, the first cutoff frequency of the active region AR may be substantially equal to the second cutoff frequency of the first peripheral region ER1 and the third cutoff frequency of the second peripheral region ER2, so that the acoustic impedance of the active region AR may be substantially equal to the acoustic impedance of the first peripheral region ER1 and the acoustic impedance of the second peripheral region ER2, and lateral waves generated in the active region AR and propagating outwardly may not be reflected back into the active region AR from the first peripheral region ER1 and the second peripheral region ER2. This reduces the resonant energy of the active region AR from being reduced by unnecessarily amplified lateral waves.

Many of the features of the bulk acoustic resonators 100, 101, 102, 103, 104, 105, 106, and 107 according to the embodiments described with reference to FIGS. 1 to 9 are also applicable to the bulk acoustic resonator 108 according to the present embodiment.

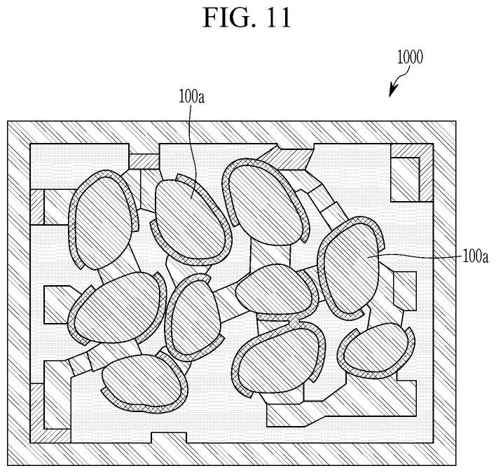

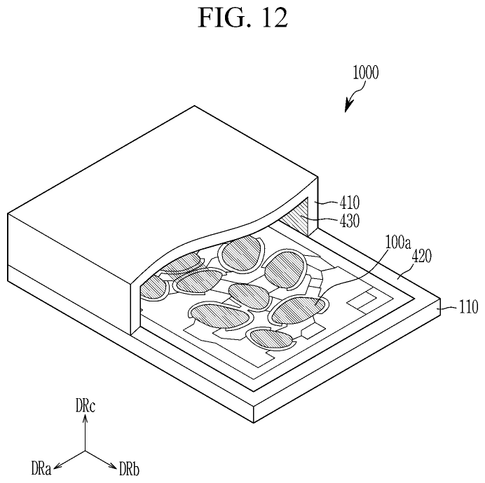

FIG. 11 is a top plan view illustrating a portion of a bulk acoustic resonator filter according to an embodiment, and FIG. 12 is a perspective view of a bulk acoustic resonator filter package according to an embodiment including the bulk acoustic resonator filter of FIG. 11.

Referring to FIGS. 11 and 12, a bulk acoustic resonator filter package 1000 according to the present embodiment may include a substrate 110, a cap 410, a plurality of acoustic resonators 100a, and a bonding member 420.

As previously described with respect to FIG. 2, the substrate 110 may include a cavity formed beneath the plurality of acoustic resonators 100a. Alternatively, instead of the cavity, as previously described with respect to FIG. 10, an acoustic reflector layer, such as a Bragg reflector layer, may formed within the substrate 110 beneath the plurality of acoustic resonators 100a.

The cap 410 may accommodate the plurality of acoustic resonators 100a, thereby protecting the plurality of acoustic resonators 100a from the external environment. The cap 410 may be formed in the form of a cover having an interior space in which the plurality of acoustic resonators 100a are accommodated.

Each of the plurality of acoustic resonators 100a may include a first electrode, a piezoelectric layer, and a second electrode stacked in a height direction DRc in which the substrate 110 and the cap 410 face each other, and may be disposed between the substrate 110 and the cap 410.

The bonding member 420 may surround the plurality of acoustic resonators 100a along planar directions DRa and DRb, and may be bonded to the cap 410 between the substrate 110 and the cap 410. For example, the bonding member 420 may be formed in an eutectic bond structure, an anodic bond structure, or a fusion bond structure of a non-conductive material, but is not limited thereto. The bonding member 420 may include a conductive ring.

A shield layer 430 is disposed on the surface of the cap 410 facing the plurality of acoustic resonators 100a and may be electrically connected to the bonding member 420. The shield layer 430 may block electromagnetic noise from the outside of the bulk acoustic resonator package 1000 from being received by the plurality of acoustic resonators 100a, and thus the performance of the bulk acoustic resonator package may be efficiently improved.

The shield layer 430 may be electrically connected to a ground portion.

Many of the features of the bulk acoustic resonators 100, 101, 102, 103, 104, 105, 106, 107, and 108 according to the embodiments described with reference to FIGS. 1 to 10 are also applicable to the bulk acoustic resonator filter package 1000 according to the present embodiment.

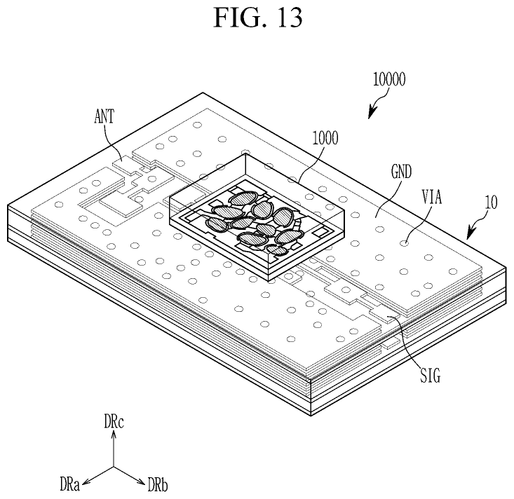

FIG. 13 is a perspective view illustrating a bulk acoustic resonator filter package substrate including the bulk acoustic resonator filter package of FIG. 12.

Referring to FIG. 13, a bulk acoustic resonator filter package substrate 10000 according to the embodiment may include a bulk acoustic resonator filter package 1000 that is disposed on a set substrate 10, for example, by being mounted on or embedded in the set substrate 10.

The set substrate 10 may be a printed circuit board having a plurality of conductive layers and a plurality of insulating layers alternately stacked, and the plurality of conductive layers may include an antenna transmission path ANT, a transceiver transmission path SIG, a ground portion GND, and a plurality of vias VIA electrically connected between the plurality of conductive layers in a height direction DRc.

The antenna transmission path ANT and the transceiver transmission path SIG may be electrically connected to RF ports of the bulk acoustic resonator filter package 1000.

Many of the features of the bulk acoustic resonators 100, 101, 102, 103, 104, 105, 106, 107, and 108 according to the embodiments described with reference to FIGS. 1 to 10 are also applicable to the bulk acoustic resonator filter package 1000 of the bulk acoustic resonator package substrate 10000.

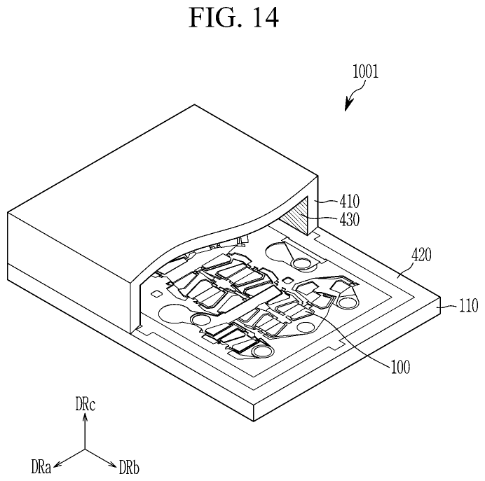

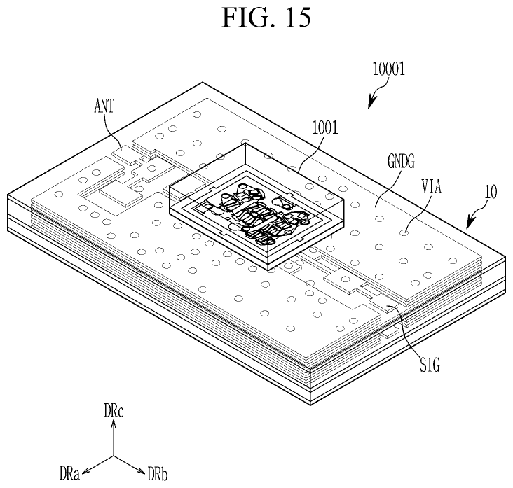

FIG. 14 is a perspective view of a bulk acoustic resonator filter package according to another embodiment, and FIG. 15 is a perspective view illustrating a bulk acoustic resonator filter package substrate including the bulk acoustic resonator filter package of FIG. 14.

Referring to FIG. 14, a bulk acoustic resonator filter package 1001 according to the present embodiment may include a substrate 110, a cap 410, a plurality of acoustic resonators 100, and a bonding member 420, similar to the bulk acoustic resonator filter package 1000 according to the embodiment previously described with reference to FIGS. 11 and 12. Specific descriptions of the same components are omitted.

Referring to FIG. 15, a bulk acoustic resonator filter package substrate 10001 according to the present embodiment may include the bulk acoustic resonator filter package 1001 disposed on a set substrate 10, for example, by being mounted on or embedded in the set substrate 10, similar to the bulk acoustic resonator filter package substrate 10000 according to the embodiment described with reference to FIG. 13.

The set substrate 10 may be a printed circuit board having a plurality of conductive layers and a plurality of insulating layers alternately stacked, and the plurality of conductive layers may include an antenna transmission path ANT, a transceiver transmission path SIG, a ground portion GND, and a plurality of vias VIA electrically connected between the plurality of conductive layers in a height direction DRc.

The antenna transmission path ANT and the transceiver transmission path SIG may be electrically connected to RF ports of the bulk acoustic resonator filter package 1001.

The planar shape, the number, and the arrangement of the plurality of acoustic resonators 100 of the bulk acoustic resonator filter package 1001 according to the present embodiment may differ from the planar shape, the number, and the arrangement of the plurality of acoustic resonators 100a of the bulk acoustic resonator filter package 1000 according to the previously described embodiment.

Many of the features of the bulk acoustic resonators 100, 101, 102, 103, 104, 105, 106, 107, and 108 according to the embodiments described with reference to FIGS. 1 to 10 are also applicable to the bulk acoustic resonator filter package 1001 of the bulk acoustic resonator package substrate 10001.

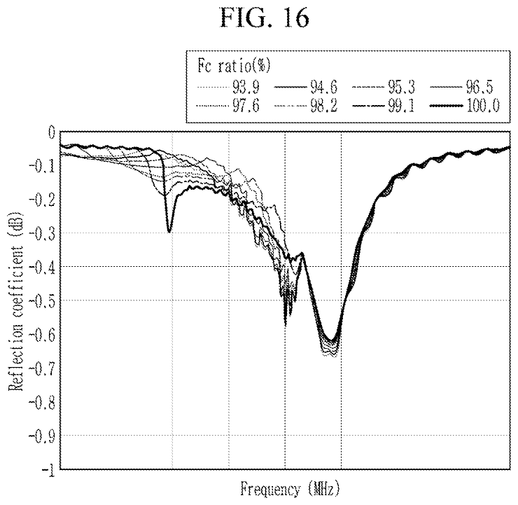

FIGS. 16 to 18 are graphs illustrating results of one simulation example of a bulk acoustic resonator.

In the present simulation example, a reflection coefficient (S11) according to the change in the value of the ratio (Fc ratio) of the cutoff frequency of the first peripheral region ER1 and the second peripheral region ER2 to the cutoff frequency of the active region AR is illustrated as graphs.

Referring to FIG. 16, it can be seen that as the value of the ratio (Fc ratio) of the cutoff frequency of the first peripheral region ER1 and the second peripheral region ER2 to the cutoff frequency of the active region AR decreases from about 1 to about 0.935, the degree of energy reduction is not large and decreases gradually.

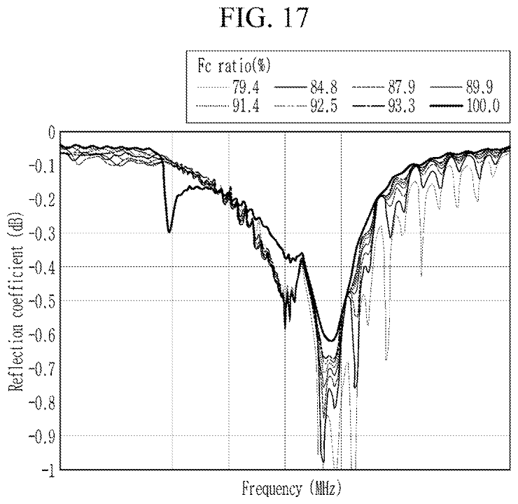

Referring to FIG. 17, it can be seen that when the value of the ratio (Fc ratio) of the cutoff frequency of the first peripheral region ER1 and the second peripheral region ER2 to the cutoff frequency of the active region AR decreases below about 0.935, the energy reduction is large and sharp.

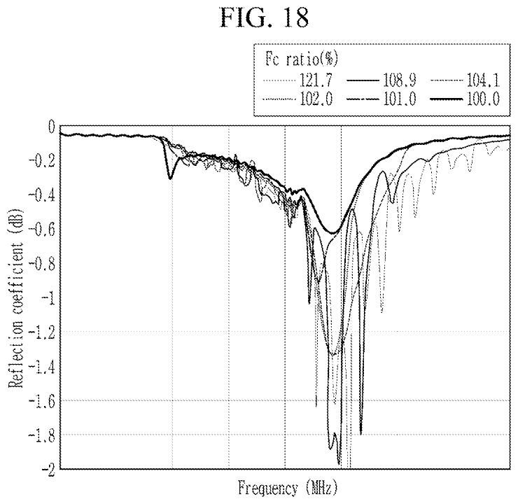

Referring to FIG. 18, it can be seen that when the value of the ratio (Fc ratio) of the cutoff frequency of the first peripheral region ER1 and the second peripheral region ER2 to the cutoff frequency of the active region AR becomes larger than about 1, the energy reduction becomes larger.

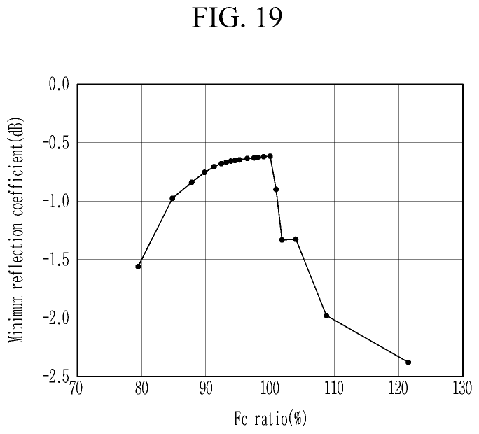

FIGS. 19 to 21 are graphs illustrating results of another simulation example of a bulk acoustic resonator.

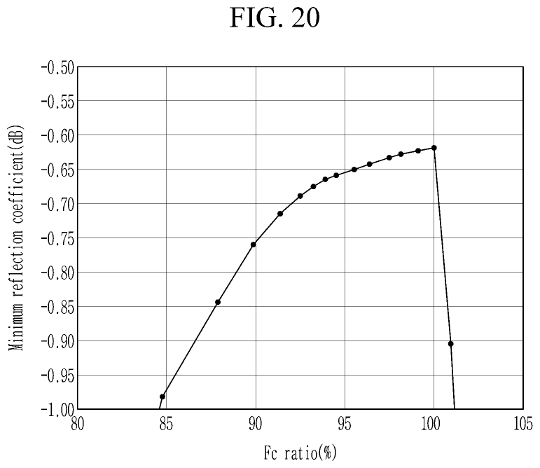

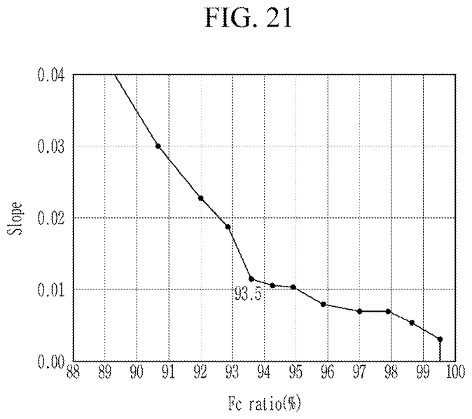

In the present experimental example, the minimum value of the reflection coefficient according to the value of the ratio (Fc ratio) of the cutoff frequency of the first peripheral region ER1 and the second peripheral region ER2 to the cutoff frequency of the active region AR is measured, and the results are shown in FIGS. 19 to 21. FIG. 20 is a graph illustrating an enlarged portion of FIG. 19, and FIG. 21 is a graph illustrating the slope of the graph in FIG. 19.

Referring to FIGS. 19 and 20, it can be seen that when the value of the ratio (Fc ratio) of the cutoff frequency of the first peripheral region ER1 and the second peripheral region ER2 to the cutoff frequency of the active region AR is from about 0.935 to about 1, the reflection coefficient is large and, accordingly, the energy loss is small.

Referring to FIG. 21, it can be seen that the value of the ratio (Fc ratio) of the cutoff frequency of the first peripheral ER1 and the second peripheral region ER2 to the cutoff frequency of the active region AR has an inflection value of about 0.935 at which a slope that is the amount of change in the reflection coefficient varies.

As such, it can be seen that when the cutoff frequency of the active region AR is substantially the same as the cutoff frequency of the first peripheral region ER1 and the second peripheral region ER2, as in the bulk acoustic resonators according to the embodiments, the energy loss in the active region AR is reduced.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A bulk acoustic resonator comprising:
an active region in which a first electrode disposed on a substrate, a piezoelectric layer disposed on the first electrode in a height direction, and a second electrode disposed on the piezoelectric layer in the height direction overlap each other in the height direction;
a peripheral region in which the first electrode or the second electrode extends outwardly from the active region so that the first electrode and the second electrode do not overlap each other in the height direction in the peripheral region; and
an auxiliary layer disposed in the peripheral region,
wherein a first cutoff frequency of the active region is substantially equal to a second cutoff frequency of the peripheral region.

2. The bulk acoustic resonator of claim 1, further comprising a cavity disposed between the substrate and the first electrode, and overlapping the active region in the height direction,
wherein a ratio of the second cutoff frequency to the first cutoff frequency is from about 0.9 to about 1.1.

3. The bulk acoustic resonator of claim 1, further comprising a boundary region disposed between the active region and the peripheral region,
wherein an end of the extended first electrode or an end of the extended second electrode and an end of the auxiliary layer overlap each other in the height direction in the boundary region.

4. The bulk acoustic resonator of claim 3, wherein a thickness of the end of the extended first electrode or a thickness of the end of the extended second electrode in the boundary region is less than a thickness of an end of the first electrode or an end of the second electrode in the active region, and
a thickness of an end of the auxiliary layer in the boundary region is less than a thickness of the auxiliary layer in the peripheral region.

5. The bulk acoustic resonator of claim 3, wherein a surface height of the piezoelectric layer in the height direction varies in the boundary region.

6. The bulk acoustic resonator of claim 3, further comprising a trench region disposed between the active region and the boundary region,
wherein a thickness of the second electrode in the trench region is less than a thickness of the second electrode in the active region.

7. The bulk acoustic resonator of claim 6, wherein the auxiliary layer further comprises an extending portion extending into the trench region, and
the extending portion of the auxiliary layer overlaps the second electrode in the trench region in the height direction.

8. The bulk acoustic resonator of claim 7, wherein a thickness of the extending portion of the auxiliary layer is less than a thickness of a remaining portion of the auxiliary layer.

9. The bulk acoustic resonator of claim 1, wherein the auxiliary layer overlaps the first electrode or the second electrode in the peripheral region with the piezoelectric layer interposed therebetween in the height direction.

10. The bulk acoustic resonator of claim 9, wherein the auxiliary layer is disposed on a lateral surface of the first electrode or the second electrode in the active region.

11. The bulk acoustic resonator of claim 9, wherein the auxiliary layer comprises an insulating material.

12. The bulk acoustic resonator of claim 11, wherein the auxiliary layer comprises at least some of materials of the piezoelectric layer.

13. The bulk acoustic resonator of claim 9, wherein a ratio of a thickness of the auxiliary layer to a thickness of the piezoelectric layer is from about 0.6 to about 0.8.

14. The bulk acoustic resonator of claim 13, wherein a ratio of a thickness of the first electrode and the second electrode to the thickness of the piezoelectric layer is from about 0.4 to about 0.6.

15. The bulk acoustic resonator of claim 9, wherein a ratio of a thickness of the auxiliary layer to a thickness of the piezoelectric layer is from about 0.5 to about 0.7.

16. The bulk acoustic resonator of claim 15, wherein a ratio of a thickness of the first electrode and the second electrode to the thickness of the piezoelectric layer is from about 0.2 to about 0.4.

17. The bulk acoustic resonator of claim 9, wherein the piezoelectric layer comprises aluminum nitride, the first electrode and the second electrode comprise molybdenum, and the auxiliary layer comprises silicon dioxide.

18. The bulk acoustic resonator of claim 1, wherein the auxiliary layer is disposed between the first electrode or the second electrode in the peripheral region and the piezoelectric layer.

19. The bulk acoustic resonator of claim 18, wherein the auxiliary layer is in contact with the first electrode or the second electrode in the peripheral region.

20. The bulk acoustic resonator of claim 18, wherein the auxiliary layer comprises an insulating layer or a conductive layer.

21. The bulk acoustic resonator of claim 18, wherein a ratio of a thickness of the auxiliary layer to a thickness of the piezoelectric layer is from about 0.2 to about 0.4.

22. The bulk acoustic resonator of claim 21, wherein a ratio of a thickness of the first electrode and the second electrode to the thickness of the piezoelectric layer is from about 0.4 to about 0.6.

23. The bulk acoustic resonator of claim 18, wherein a ratio of a thickness of the auxiliary layer to a thickness of the piezoelectric layer is from about 0.1 to about 0.3.

24. The bulk acoustic resonator of claim 23, wherein a ratio of a thickness of the first electrode and the second electrode to the thickness of the piezoelectric layer is from about 0.2 to about 0.4.

25. The bulk acoustic resonator of claim 18, wherein the piezoelectric layer comprises aluminum nitride, the first electrode and the second electrode comprise molybdenum, and the auxiliary layer comprises silicon dioxide.

26. The bulk acoustic resonator of claim 1, wherein the auxiliary layer overlaps the piezoelectric layer in the height direction with the first electrode or the second electrode in the peripheral region being interposed therebetween.

27. The bulk acoustic resonator of claim 26, wherein the auxiliary layer is in contact with the first electrode or the second electrode in the peripheral region.

28. The bulk acoustic resonator of claim 26, wherein the auxiliary layer comprises an insulating material or a conductive material.

29. The bulk acoustic resonator of claim 26, wherein a ratio of a thickness of the auxiliary layer to a thickness of the piezoelectric layer is from about 0.7 to about 0.9.

30. The bulk acoustic resonator of claim 29, wherein a ratio of a thickness of the first electrode and the second electrode to the thickness of the piezoelectric layer is from about 0.4 to about 0.6.

31. The bulk acoustic resonator of claim 26, wherein a ratio of a thickness of the auxiliary layer to a thickness of the piezoelectric layer is from about 0.6 to about 0.8.

32. The bulk acoustic resonator of claim 31, wherein a ratio of a thickness of the first electrode and the second electrode to the thickness of the piezoelectric layer is from about 0.2 to about 0.4.

33. The bulk acoustic resonator of claim 26, wherein the piezoelectric layer comprises aluminum nitride, the first electrode and the second electrode comprise molybdenum, and the auxiliary layer comprises silicon dioxide.

34. The bulk acoustic resonator of claim 1, further comprising an acoustic reflector layer disposed within the substrate and overlapping the active region,
wherein a ratio of the second cutoff frequency to the first cutoff frequency is substantially equal to 1.

35. The bulk acoustic resonator of claim 34, wherein the ratio of the second cutoff frequency to the first cutoff frequency is from about 0.9 to about 1.1.

36. The bulk acoustic resonator of claim 1, wherein the peripheral region comprises:
a first peripheral region in which the first electrode extends outwardly from the active region and does not overlap the second electrode in the height direction; and
a second peripheral region in which the second electrode extends outwardly from the active region and does not overlap the first electrode in the height direction, and
the auxiliary layer comprises:
a first auxiliary layer disposed in the first peripheral region and overlapping the extending first electrode in the height direction; and
a second auxiliary layer disposed in the second peripheral region and overlapping the extending second electrode in the height direction.

37. The bulk acoustic resonator of claim 36, wherein the first auxiliary layer is disposed between the piezoelectric layer and the first electrode, and
the second auxiliary layer overlaps the second electrode in the height direction with the piezoelectric layer interposed therebetween.

38. A bulk acoustic resonator comprising:
an active region in which a first electrode, a piezoelectric layer disposed on the first electrode in a height direction, and a second electrode disposed on the piezoelectric layer in the height direction overlap each other in the height direction; and
a peripheral region disposed on a circumference of the active region, wherein the piezoelectric layer, the auxiliary layer, and an extending portion of the first electrode or an extending portion of the second electrode extending outwardly from the active region overlap each other in the height direction,
wherein a first cutoff frequency of the active region is substantially equal to a second cutoff frequency of the peripheral region.

39. The bulk acoustic resonator of claim 38, further comprising a cavity overlapping the active region in the height direction,
wherein a ratio of the second cutoff frequency to the first cutoff frequency is from about 0.9 to about 1.1.

40. The bulk acoustic resonator of claim 38, further comprising an acoustic reflector layer overlapping the active region in the height direction,
wherein a ratio of the second cutoff frequency to the first cutoff frequency is from about 0.9 to about 1.1.

41. A bulk acoustic resonator comprising:
an active region in which a first electrode disposed on a substrate, a piezoelectric layer disposed on the first electrode in a height direction, and a second electrode disposed on the piezoelectric layer in the height direction overlap each other in the height direction;
a first peripheral region in which the first electrode and the piezoelectric layer extend outwardly from the active region so that the first electrode and the second electrode do not overlap each other in the height direction in the first peripheral region;
a second peripheral region in which the second electrode and the piezoelectric layer extend outwardly from the active region so that the first electrode and the second electrode do not overlap each other in the height direction in the second peripheral region;
a first auxiliary layer disposed in the first peripheral region so that the first electrode is disposed between the first auxiliary layer and the piezoelectric layer in the height direction in the first peripheral region; and
a second auxiliary layer disposed in the second peripheral region so that the second electrode is disposed between the second auxiliary layer and the piezoelectric layer in the height direction in the second peripheral region.

42. The bulk acoustic resonator of claim 41, wherein a first cutoff frequency of the active region is substantially equal to a second cutoff frequency of the first peripheral region and a third cutoff frequency of the second peripheral region.

43. The bulk acoustic resonator of claim 41, wherein a surface height of the first electrode in the height direction in the first peripheral region is different from a surface height of the first electrode in the height direction in the active region, and
a surface height of the second electrode in the height direction in the second peripheral region is different from a surface height of the second electrode in the height direction in the active region.

44. The bulk acoustic resonator of claim 41, wherein a surface height of the first electrode in the height direction in the first peripheral region is the same as a surface height of the first electrode in the height direction in the active region, and
a surface height of the second electrode in the height direction in the second peripheral region is the same as a surface height of the second electrode in the height direction in the active region.

45. The bulk acoustic resonator of claim 41, wherein a ratio of a thickness of the first auxiliary layer and the second auxiliary layer to a thickness of the piezoelectric layer is from about 0.7 to about 0.9, and
a ratio of a thickness of the first electrode and the second electrode to a thickness of the piezoelectric layer is from about 0.4 to about 0.6.

46. The bulk acoustic resonator of claim 41, wherein a ratio of a thickness of the first auxiliary layer and the second auxiliary layer to a thickness of the piezoelectric layer is from about 0.6 to about 0.8, and
a ratio of a thickness of the first electrode and the second electrode to a thickness of the piezoelectric layer is from about 0.2 to about 0.4.
